(19) United States
(12) Patent Application Publication
(10) Pub. No.: US 2008/0042165 A1
(43) Pub. Date: Feb. 21, 2008

(54) Semiconductor device and method for manufacturing semiconductor device

(75) Inventor: Taro Sugizaki, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 11/878,684

(22) Filed: Jul. 26, 2007

(30) Foreign Application Priority Data
Aug. 2, 2006 (JP) 2006-210618

(51) Int. Cl. H01L 29/74; H01L 21/332

(52) U.S. Cl. 257/133; 438/135; 257/E27.112; 257/E21.703

(57) ABSTRACT

A semiconductor device includes a thyristor configured to be formed through sequential joining of a first region of a first conductivity type, a second region of a second conductivity type opposite to the first conductivity type, a third region of the first conductivity type, and a fourth region of the second conductivity type, and have a gate formed over the third region. The first to fourth regions are formed in a silicon germanium region or germanium region.

### CROSS REFERENCES TO RELATED APPLICATIONS

The present invention contains subject matter related to Japanese Patent Application JP 2006-210618 filed with the Japan Patent Office on Aug. 2, 2006, the entire contents of which being incorporated herein by reference.

### BACKGROUND OF THE INVENTION

1. Field of the Invention

The present invention relates to a semiconductor device having a thyristor and a method for manufacturing the semiconductor device.

2. Description of the Related Art

There has been proposed a memory (for an SRAM in particular) that employs a thyristor of which turn-on and turn-off characteristics are controlled by a gate electrode realized over the thyristor, and is connected in series to an access transistor (this memory will be referred to as a T-RAM, hereinafter). The memory operation thereof is realized in such a way that the off-region of the thyristor is defined as “0” and the on-region thereof as “1”.

The thyristor is the combination of a PNP bipolar transistor and an NPN bipolar transistor. The thyristor basically operates as a bipolar transistor, and therefore, is basically different from a unipolar element such as a MOS transistor in the operation principle.

Basically, the thyristor arises from sequential joining of a p-region p1, n-region n1, p-region p2, and n-region n2, and is formed of e.g. four layers of n-type silicon and p-type silicon. Hereinafter, this basic structure is represented as p1/n1/p2/n2. Two kinds of structures have been proposed by T-RAM, Inc. In one structure, a p1/n1/p2/n2 structure is vertically formed over a silicon substrate. In the other structure, a p1/n1/p2/n2 structure is laterally formed in a silicon layer by using an SOI substrate.

FIG. 11 shows one example of a thyristor formed in a typical bulk silicon semiconductor substrate. Referring to FIG. 11, for a thyristor 110, a second p-region p2 is formed in a well region 112 formed in a silicon semiconductor substrate 111. Over the second p-region p2, a gate electrode 114 is formed with the intermediary of a gate insulating film 113. In the second p-region p2 on both the lateral sides of the gate electrode 114, a first n-region n1 and a second n-region n2 are formed. Furthermore, on the first n-region n1 (n-type diffusion layer on the right side in the drawing), a first p-region p1 is formed. Therefore, the thyristor 110 has a structure obtained through sequential joining of the first p-region p1, the first n-region n1, the second p-region p2, and the second n-region n2.

In either structure, a gate electrode based on a MOS structure is provided over the region p2 of the p1/n1/p2/n2 structure, which enables high-speed operation. In a typical thyristor, the speed of switching from the on-state to the off-state and from the off-state to the on-state is low, and in particular, the speed of switching from the on-state to the off-state is low.

For switching from the on-state to the off-state, a negative voltage is applied to an anode electrode A while a positive voltage is applied to a cathode electrode K, so that the thyristor is reverse biased. However, when only this operation is carried out, it takes several milliseconds for the thyristor to be switched to the off-state.

On the other hand, in order to enhance the switch-off speed of existing typical thyristors, a method is widely employed in which platinum (Pt) or the like is diffused in the n-region n1 to thereby shorten the lifetime of the minority carriers in the n-region n1 for achievement of enhanced speed.

For example, as shown in FIG. 12A, in a thyristor-structure semiconductor device, a first p-region p1, first n-region n1, second p-region p2, and second n-region n2 are sequentially provided, so that a p1/n1/p2/n2 structure is formed. Furthermore, an anode electrode A is connected to the first p-region p1 provided on one end side, while a cathode electrode K is connected to the second n-region n2 provided on the opposite end side. Therefore, a basic structure of the anode electrode A—p1/n1/p2/n2—the cathode electrode K is constructed.

In this thyristor-structure semiconductor device, as shown in FIG. 12B, upon application of a forward bias between the anode and cathode electrodes A and K, holes are supplied from the p-region p1 connected to the anode electrode A into the n-region n1, while electrons are supplied from the n-region n2 connected to the cathode electrode K into the p-region p2. These holes and electrons are recombined at the junction between the n-region n1 and the p-region p2, and thus a current flows, which is equivalent to the on-state of the semiconductor device.

In contrast, as shown in FIGS. 12C and 12D, applying a reverse bias between the anode and cathode electrodes A and K causes the thyristor to enter the off-state. However, it takes a time period as long as several milliseconds for the thyristor to enter the substantial off-state. Specifically, if the thyristor has entered the on-state, merely applying a reverse bias between the anode and cathode electrodes A and K does not cause the thyristor to spontaneously enter the off-state. By decreasing the current to below the holding current or turning the power off, all of the excess carriers that flow in the n-region n1 and the p-region p2 can be swept out of these regions or be recombined.

For shortening of the lifetime through recombination of carriers, a method of diffusing platinum like the existing method would be available. However, transition metals such as platinum are contamination substances in the field of a silicon CMOS semiconductor (in particular, in the front half of a wafer process (in a FEOL (Front-End of Line) process), and hence this method is not practical.

With reference to FIG. 13, a description will be made below about the relationship, in the above-described thyristor-structure semiconductor device, between the voltage (VAK) between the anode and cathode electrodes A and K and the current (I) that flows through this semiconductor device.

Referring to FIG. 13, when the voltage VAK reaches the critical voltage VFB in application of positive voltage to the anode A, the pn junction between the n-region n1 and the p-region p2 is forward biased. At this time, the voltage V_{AK} decreases and the flow of a current larger than the holding current I_{H} starts. In contrast, when the voltage V_{AK} is lower than the critical voltage V_{FB}, the switching current Is smaller than the holding current I_{H} flows. It is not until the voltage V_{AK} surpasses the critical voltage V_{FB} that the flow of a current larger than the holding current I_{H} starts.

In order to enhance the speed of the above-described switching operation, there has been proposed a structure in which a gate electrode based on a MOS structure is provided by disposing an electrode over the p-region p2 with the intermediary of an insulating film. The following documents are examples of the proposal: U.S. Pat. No. 6,462,359 (B1); Farid Nemati and James D. Plummer, “A Novel High Density, Low Voltage SRAM Cell with a Vertical NDR Device”, 1998 IEEE, VLSI Technology Tech. Dig., p. 66, 1998; Farid Nemati and James D. Plummer, “A Novel Thyristor-based SRAM Cell (T-RAM) for High-Speed, Low-Voltage, Giga-scale Memories”, 1999 IEEE IEDM Tech., p. 283, 1999; Farid Nemati, Hyun-Jin Cho, Scott Robins, Rajesh Gupta, Marc Tarabbia, Kevin J. Yang, Dennis Hayes, Vasudevan Gopalakrishnan, “Fully Planar 0.562 μm2 T-RAM Cell in a 130 nm SOI CMOS Logic Technology for High-Density High-Performance SRAMs”, 2004 IEEE IEDM Tech., p. 273, 2004; and M. Stoisiek and H. Strack, “MOS GTO-A TURN OFF THYRISTOR WITH MOS-CONTROLLED EMITTER SHORTS”, 1985 IEEE IEDM Tech., p. 158, 1985.

### SUMMARY OF THE INVENTION

Existing thyristor devices however involve a problem that the speed of switching from the on-state to the off-state is low because the carrier mobility in the n-region n1 between the p-regions p1 and p2 is low and hence it takes a long time for the carriers to be swept out of the n-region n1.

There is a need for the present invention to enhance the mobility to thereby increase the speed of switching from the on-state to the off-state.

According to an embodiment of the present invention, there is provided a semiconductor device (first semiconductor device) that includes a thyristor configured to be formed through sequential joining of a first region of a first conductivity type, a second region of a second conductivity type opposite to the first conductivity type, a third region of the first conductivity type, and a fourth region of the second conductivity type, and have a gate formed over the third region. The first to fourth regions are formed in a silicon germanium region or germanium region.

According to another embodiment of the present invention, there is provided a semiconductor device (second semiconductor device) that includes a thyristor configured to be formed through sequential joining of a first region of a first conductivity type, a second region of a second conductivity type opposite to the first conductivity type, a third region of the first conductivity type, and a fourth region of the second conductivity type, and have a gate formed over the third region. The second region is formed of a silicon germanium layer or germanium layer.

In the first and second semiconductor devices according to embodiments of the present invention, the second region in the thyristor is formed in a silicon germanium layer or germanium layer having mobility higher than that of silicon. Thus, the mobility of carriers in the second region can be enhanced. This can increase the speed of sweeping of the carriers out of the second region, which can enhance the speed of switching from the on-state to the off-state. In a related art, the time period until the switching to the off-state from the on-state is limited by the time period until the disappearance of excess carriers in the second region (or in both the first region and the second region), i.e., by the lifetime of the carriers. Therefore, the switching speed is not sufficiently high. In the first and second semiconductor devices, because the carrier mobility is enhanced, increase in the speed of switching from the off-state to the on-state can also be expected as a synergetic effect. It is generally known that the carrier mobility of germanium is higher than that of silicon. For example, the mobility of electrons and holes in silicon is 1600 cm²/V·s and 430 cm²/V·s, respectively. In contrast, the mobility of electrons and holes in germanium is 3900 cm²/V·s and 1900 cm²/V·s, respectively. That is, both the mobility of electrons and that of holes in germanium are higher, and in particular, the mobility of holes in germanium is as high as about five times that in silicon. Therefore, by using germanium or silicon germanium, which is a mixture of silicon and germanium with high carrier mobility, as the material of at least the second region, the switching speed of the thyristor can be enhanced.

According to an embodiment of the present invention, there is provided a manufacturing method (first manufacturing method) for a semiconductor device that includes a thyristor formed through sequential joining of a first region of a first conductivity type, a second region of a second conductivity type opposite to the first conductivity type, a third region of the first conductivity type, and a fourth region of the second conductivity type, and has a gate formed over the third region. The method includes the step of forming the first to fourth regions in a silicon germanium region or germanium region.

According to another embodiment of the present invention, there is provided a manufacturing method (second manufacturing method) for a semiconductor device that includes a thyristor formed through the sequential joining of a first region of a first conductivity type, a second region of a second conductivity type opposite to the first conductivity type, a third region of the first conductivity type, and a fourth region of the second conductivity type, and has a gate formed over the third region. The method includes the step of forming the second region by using a silicon germanium layer or germanium layer.

In the methods for manufacturing a semiconductor device according to embodiments of the present invention (first and second manufacturing methods), the second region in the thyristor is formed by using a silicon germanium layer or germanium layer having mobility higher than that of silicon. Thus, the mobility of carriers in the second region can be enhanced. This can increase the speed of sweeping of the carriers out of the second region, which can enhance the speed of switching from the on-state to the off-state. Furthermore, because the carrier mobility is enhanced, increase in the speed of switching from the off-state to the on-state can also be expected as a synergetic effect. It is generally known that the carrier mobility of germanium is higher than that of silicon. For example, the mobility of electrons and holes in silicon is 1600 cm²/V·s and 430 cm²/V·s, respectively. In contrast, the mobility of electrons and holes in germanium is 3900 cm²/V·s and 1900 cm²/V·s, respectively. That is, both the mobility of electrons and that of holes in germanium are higher, and in particular, the mobility of holes in germanium is as high as about five times that in silicon. Therefore, by using germanium or silicon germanium, which is a mixture of silicon and germanium with high carrier mobility, as the material of at least the second region, the switching speed of the thyristor can be enhanced.

In a semiconductor device according to an embodiment of the present invention, at least the second region is formed of a silicon germanium layer or germanium layer, and thus the mobility of carriers in the second region can be enhanced. Therefore, the switching speed of the thyristor can be enhanced advantageously. This offers an advantage that a semiconductor device having a high-speed thyristor can be provided.

In a method for manufacturing a semiconductor device according to an embodiment of the present invention, at least the second region is formed by using a silicon germanium layer or germanium layer, and thus the mobility of carriers in the second region can be enhanced. Therefore, the switching speed of the thyristor can be enhanced advantageously. This offers an advantage that a semiconductor device having a high-speed thyristor can be manufactured.

### BRIEF DESCRIPTION OF THE DRAWINGS

FIG. 1 is a sectional view schematically showing the structure of a semiconductor device according to one embodiment (first embodiment) of the present invention;

FIG. 2 is a sectional view schematically showing the structure of a semiconductor device according to one embodiment (second embodiment) of the present invention;

FIG. 3 is a sectional view schematically showing the structure of a semiconductor device according to one embodiment (third embodiment) of the present invention;

FIG. 4 is a sectional view schematically showing the structure of a semiconductor device according to one embodiment (fourth embodiment) of the present invention;

FIG. 5 is a sectional view schematically showing the structure of a semiconductor device according to one embodiment (fifth embodiment) of the present invention;

FIGS. 6A to 6H are sectional views showing manufacturing steps of a method for manufacturing a semiconductor device according to one embodiment (first embodiment) of the present invention;

FIGS. 7A to 7I are sectional views showing manufacturing steps of a method for manufacturing a semiconductor device according to one embodiment (second embodiment) of the present invention;

FIGS. 8A to 8C are sectional views showing manufacturing steps of a method for manufacturing a semiconductor device according to one embodiment (third embodiment) of the present invention;

FIGS. 9A to 9C are sectional views showing manufacturing steps of a method for manufacturing a semiconductor device according to one embodiment (fourth embodiment) of the present invention;

FIGS. 10A and 10D are sectional views showing manufacturing steps of a method for manufacturing a semiconductor device according to one embodiment (fifth embodiment) of the present invention;

FIG. 11 is a sectional view schematically showing the structure of one example of an existing semiconductor device;

FIGS. 12A to 12D are diagrams showing the schematic structure and operation of an existing thyristor-structure semiconductor device; and

FIG. 13 is a diagram showing the voltage-current (V-I) characteristic of an existing thyristor-structure semiconductor device.

### DETAILED DESCRIPTION OF THE PREFERRED EMBODIMENTS

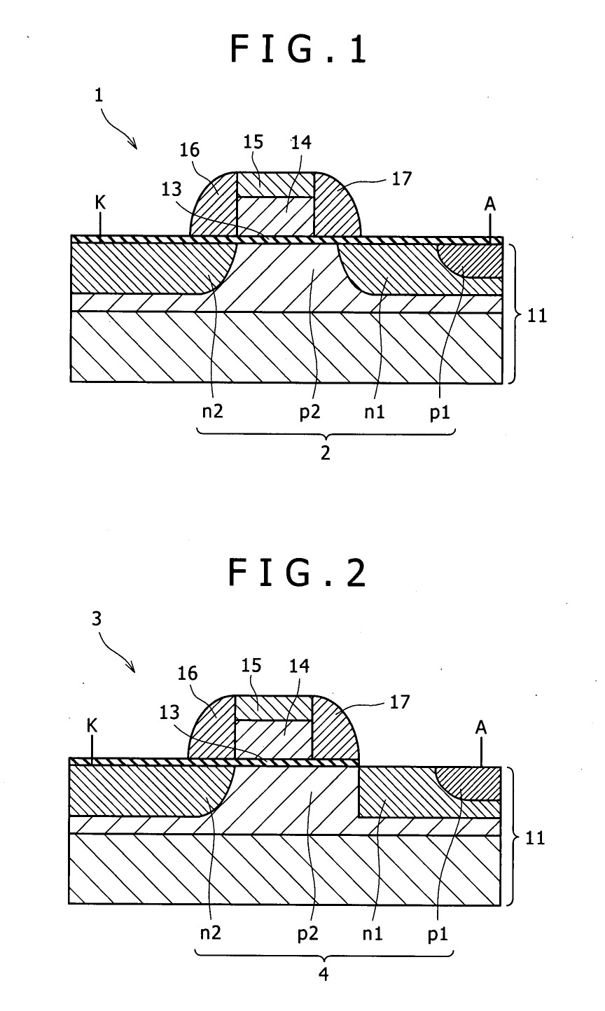

A semiconductor device according to one embodiment (first embodiment) of the present invention will be described below with reference to FIG. 1 as a sectional view of a schematic structure.

As shown in FIG. 1, a semiconductor device 1 includes a thyristor 2 arising from sequential joining of a first region (hereinafter, referred to as a first p-region) p1 of a first conductivity type (hereinafter, defined as the p-type), a second region (hereinafter, referred to as a first n-region) n1 of a second conductivity type (hereinafter, defined as the n-type) opposite to the first conductivity type, a third region (hereinafter, referred to as a second p-region) p2 of the first conductivity type (p-type), and a fourth region (hereinafter, referred to as a second n-region) n2 of the second conductivity type (n-type). Details of the semiconductor device 1 will be described below.

A germanium layer 12 is formed on a semiconductor substrate 11. In this germanium layer 12, the second p-region p2 of the first conductivity type (p-type) is formed. It is also possible to form the second p-region p2 in the whole of the germanium layer 12. Furthermore, it is also possible to employ a silicon germanium layer as the germanium layer 12. That is, this layer is composed of a material having a carrier mobility higher than that of silicon. As the semiconductor substrate 11, e.g. a silicon substrate is used.

The second p-region p2 is formed by introducing, as a p-type dopant, e.g. boron (B) with a dopant concentration of about 5×10¹⁷ cm⁻³. It is desirable that the dopant concentration in the second p-region p2 be about 1×10¹⁶ cm⁻³ to 1×10¹⁹ cm⁻³. Basically, this dopant concentration should be lower than that in the first n-region n1 of the second conductivity type (n-type) to be described later. As the p-type dopant, besides boron (B), another p-type impurity such as indium (In) is available.

Over the second p-region p2, a gate electrode 14 is formed with the intermediary of a gate insulating film 13. A hard mask (not shown) may be formed over the gate electrode 14. The gate insulating film 13 is formed of e.g. a silicon oxide (SiO₂) film and has a thickness of about 1 nm to 10 nm. The material of the gate insulating film 13 is not limited to silicon oxide (SiO₂), but it is also possible to use silicon oxynitride (SiON) or use another gate insulating film material applicable to a typical CMOS transistor, such as hafnium oxide (HfO₂), hafnium oxynitride (HfON), aluminum oxide (Al₂O₃), hafnium silicate (HfSiO), nitrided hafnium silicate (HfSiON), or lanthanum oxide (La₂O₃).

The gate electrode 14 is generally formed of poly-crystalline silicon. It is also possible to employ a metal gate electrode as the gate electrode 14 or alternatively form the gate electrode 14 by using silicon germanium (SiGe) or the like. A hard mask used in the formation of the gate electrode 14 may be left over the gate electrode 14. This hard mask is formed of e.g. a silicon oxide (SiO₂) film, silicon nitride (Si₃N₄) film, or the like.

Sidewalls 16 and 17 are formed on the side faces of the gate electrode 14. These sidewalls 16 and 17 are formed of a silicon oxide (SiO₂) film, silicon nitride (Si₃N₄) film, or a multi-layer film of these films. Over the area from the second region n1 to the gate electrode 14, a salicide block (not shown) used when a salicide process is carried out for the anode side and cathode side may be formed.

In the second p-region p2 on one lateral side of the gate electrode 14, the first n-region n1 of the second conductivity type (n-type) is formed. This first n-region n1 is formed by introducing e.g. phosphorous (P) as an n-type dopant to a dopant concentration of e.g. 1.5×10¹⁹ cm⁻³. It is desirable that this dopant concentration be about 1×10¹⁸ cm⁻³ to 1×10²⁰ cm⁻³, and this dopant concentration should be higher than that in the second p-region p2. Instead of phosphorous, another n-type dopant such as arsenic or antimony can also be used.

In the second p-region p2 on the other lateral side of the gate electrode 14, the second n-region n2 of the second conductivity type (n-type) is formed. This second n-region n2 is formed by introducing e.g. arsenic (As) as an n-type dopant to a dopant concentration of e.g. 5×10²⁰ cm⁻³. It is desirable that this dopant concentration be about 1×10¹⁸ cm⁻³ to 1×10²¹ cm⁻³, and this dopant concentration should be higher than that in the second p-region p2. Instead of arsenic, another n-type dopant such as phosphorous or antimony can also be used.

Furthermore, on the first n-region n1, the first p-region p1 of the first conductivity type (p-type) is formed. The first p-region p1 is so formed that the concentration of boron (B) in the film is set to 1×10²⁰ cm⁻³ for example. It is desirable that this dopant (boron) concentration be about 1×10¹⁸ cm⁻³ to 1×10²¹ cm⁻³.

An anode electrode A is connected to the first p-region p1, and a cathode electrode K is connected to the second n-region n2. Over the first p-region p1, the second n-region n2, and the gate electrode 14, a silicide (titanium silicide, cobalt silicide, nickel silicide, or the like) may be formed, although not shown in the drawing.

In the semiconductor device 1 in which the above-described thyristor 2 is used as a memory cell, a field effect transistor (not'shown) may be formed as a selection transistor in the semiconductor substrate 11. Specifically, although not shown in the drawing, e.g. a well region of the first conductivity type (p-type) is formed in the semiconductor substrate 11, and the field effect transistor is formed by using this well region. For this field effect transistor, a gate electrode is formed over the p-type well region with the intermediary of a gate insulating film, and sidewalls are formed on both the sides of the gate electrode. Furthermore, in the p-type well region under the sidewalls, extension regions of the source and drain are formed. In addition, a drain region and a source region are formed in the p-type well region on one and the other lateral sides of the gate electrode with the intermediary of the extension region. The source region is connected to the second n-region n2 (cathode side) in the thyristor 2 via an interconnection (cathode electrode K). Furthermore, the drain region is connected to a bit line.

In the semiconductor device 1 according to an embodiment of the present invention, the first n-region n1 as the second region in the thyristor 2 and the first p-region p1 as the first region are formed in the germanium layer 12 or silicon germanium layer having mobility higher than that of silicon. Thus, the mobility of carriers in the first n-region n1 and the first p-region p1 as the first region can be enhanced. This can increase the speed of sweeping of the carriers out of the first n-region n1 and the first p-region p1 as the first region, which can enhance the speed of switching from the on-state to the off-state. Furthermore, because the carrier mobility is enhanced, increase in the speed of switching from the off-state to the on-state can also be expected as a synergetic effect. It is generally known that the carrier mobility of germanium is higher than that of silicon. For example, the mobility of electrons and holes in silicon is 1600 cm²/V·s and 430 cm²/V·s, respectively. In contrast, the mobility of electrons and holes in germanium is 3900 cm²/V·s and 1900 cm²/V·s, respectively. That is, both the mobility of electrons and that of holes in germanium are higher, and in particular, the mobility of holes in germanium is as high as about five times that in silicon. Therefore, by using germanium or silicon germanium, which is a mixture of silicon and germanium with high carrier mobility, as the material of at least a region in which the first n-region n1 and the first p-region p1 are formed, the switching speed of the thyristor 2 can be enhanced. This offers an advantage that the semiconductor device 1 having a high-speed thyristor can be provided.

A semiconductor device according to one embodiment (second embodiment) of the present invention will be described below with reference to FIG. 2 as a sectional view of a schematic structure.

As shown in FIG. 2, a semiconductor device 3 includes a thyristor 4 arising from sequential joining of a first, region (hereinafter, referred to as a first p-region) p1 of a first conductivity type (hereinafter, defined as the p-type), a second region (hereinafter, referred to as a first n-region) n1 of a second conductivity type (hereinafter, defined as the n-type) opposite to the first conductivity type, a third region (hereinafter, referred to as a second p-region) p2 of the first conductivity type (p-type), and a fourth region (hereinafter, referred to as a second n-region) n2 of the second conductivity type (n-type). Details of the semiconductor device 3 will be described below.

In a semiconductor substrate 11, the second p-region p2 of the first conductivity type (p-type) is formed. As a semiconductor substrate 11, e.g. a bulk silicon substrate is used. The second p-region p2 is formed by introducing, as a p-type dopant, e.g. boron (B) with a dopant concentration of about 5×10¹⁷ cm⁻³. It is desirable that the dopant concentration in the second p-region p2 be about 1×10¹⁶ cm⁻³ to 1×10¹⁹ cm⁻³. Basically, this dopant concentration should be lower than that in the first n-region n1 of the second conductivity type (n-type) to be described later. As the p-type dopant, besides boron (B), another p-type impurity such as indium (In) is available.

Over the second p-region p2, a gate electrode 14 is formed with the intermediary of a gate insulating film 13. A hard mask (not shown) may be formed over the gate electrode 14. The gate insulating film 13 is formed of e.g. a silicon oxide (SiO₂) film and has a thickness of about 1 nm to 10 nm. The material of the gate insulating film 13 is not limited to silicon oxide (SiO₂), but it is also possible to use silicon oxynitride (SiON) or use another gate insulating film material applicable to a typical CMOS transistor, such as hafnium oxide (HfO₂), hafnium oxynitride (HfON), aluminum oxide (Al₂O₃), hafnium silicate (HfSiO), nitrided hafnium silicate (HfSiON), or lanthanum oxide (La₂O₃).

The gate electrode 14 is generally formed of poly-crystalline silicon. It is also possible to employ a metal gate electrode as the gate electrode 14 or alternatively form the gate electrode 14 by using silicon germanium (SiGe) or the like. A hard mask used in the formation of the gate electrode 14 may be left over the gate electrode 14. This hard mask is formed of e.g. a silicon oxide (SiO₂) film, silicon nitride (Si₃N₄) film, or the like.

Sidewalls 16 and 17 are formed on the side faces of the gate electrode 14. These sidewalls 16 and 17 are formed of a silicon oxide (SiO₂) film, silicon nitride (Si₃N₄) film, or a multi-layer film of these films. Over the area from the second region n1 to the gate electrode 14, a salicide block (not shown) used when a salicide process is carried out for the anode side and cathode side may be formed.

In the second p-region p2 on one lateral side of the gate electrode 14, the first n-region n1 of the second conductivity type (n-type) is formed. The first n-region n1 is formed of a germanium layer or silicon germanium layer having a carrier mobility higher than that of silicon. The first n-region n1 is formed by epitaxially growing a germanium layer or silicon germanium layer in a recess 18 formed in the second p-region p2, and is formed by introducing e.g. phosphorous (P) as an n-type dopant to a dopant concentration of e.g. 1×10¹⁸ cm⁻³. It is desirable that this dopant concentration be about 1×10¹⁸ cm⁻³ to 1×10²⁰ cm⁻³, and this dopant concentration should be higher than that in the second p-region p2. Instead of phosphorous, another n-type dopant such as arsenic or antimony can also be used.

In the second p-region p2 on the other lateral side of the gate electrode 14, the second n-region n2 of the second conductivity type (n-type) is formed. This second n-region n2 is formed by introducing e.g. arsenic (As) as an n-type dopant to a dopant concentration of e.g. 5×10²⁰ cm⁻³. It is desirable that this dopant concentration be about 1×10¹⁸ cm⁻³ to 1×10²¹ cm⁻³, and this dopant concentration should be higher than that in the second p-region p2. Instead of arsenic, another n-type dopant such as phosphorous or antimony can also be used.

Furthermore, on the first n-region n1, the first p-region p1 of the first conductivity type (p-type) is formed. The first p-region p1 is so formed that the concentration of boron (B) in the film is set to 1×10²⁰ cm⁻³ for example. It is desirable that this dopant (boron) concentration be about 1×10¹⁸ cm⁻³ to 1×10²¹ cm⁻³.

An anode electrode A is connected to the first p-region p1, and a cathode electrode K is connected to the second n-region n2. Over the first p-region p1, the second n-region n2, and the gate electrode 14, a silicide (titanium silicide, cobalt silicide, nickel silicide, or the like) may be formed, although not shown in the drawing.

In the semiconductor device 3 in which the above-described thyristor 4 is used as a memory cell, a field effect transistor (not shown) may be formed as a selection transistor in the semiconductor substrate 11. Specifically, although not shown in the drawing, e.g. a well region of the first conductivity type (p-type) is formed in the semiconductor substrate 11, and the field effect transistor is formed by using this well region. For this field effect transistor, a gate electrode is formed over the p-type well region with the intermediary of a gate insulating film, and sidewalls are formed on both the sides of the gate electrode. Furthermore, in the p-type well region under the sidewalls, extension regions of the source and drain are formed. In addition, a drain region and a source region are formed in the p-type well region on one and the other lateral sides of the gate electrode with the intermediary of the extension region. The source region is connected to the second n-region n2 (cathode side) in the thyristor 4 via an interconnection (cathode electrode K). Furthermore, the drain region is connected to a bit line.

In the semiconductor device 3 according to an embodiment of the present invention, the first n-region n1 as the second region in the thyristor is formed in a germanium layer or silicon germanium layer having mobility higher than that of silicon. Thus, the mobility of carriers in the first n-region n1 can be enhanced. This can increase the speed of sweeping of the carriers out of the first n-region n1, which can enhance the speed of switching from the on-state to the off-state. Furthermore, because the carrier mobility is enhanced, increase in the speed of switching from the off-state to the on-state can also be expected as a synergetic effect. It is generally known that the carrier mobility of germanium is higher than that of silicon. For example, the mobility of electrons and holes in silicon is 1600 cm²/V·s and 430 cm²/V·s, respectively. In contrast, the mobility of electrons and holes in germanium is 3900 cm²/V·s and 1900 cm²/V·s, respectively. That is, both the mobility of electrons and that of holes in germanium are higher, and in particular, the mobility of holes in germanium is as high as about five times that in silicon. Therefore, by using germanium or silicon germanium as the material of at least the first n-region n1, the switching speed of the thyristor 4 can be enhanced. This offers an advantage that the semiconductor device 3 having a high-speed thyristor can be provided.

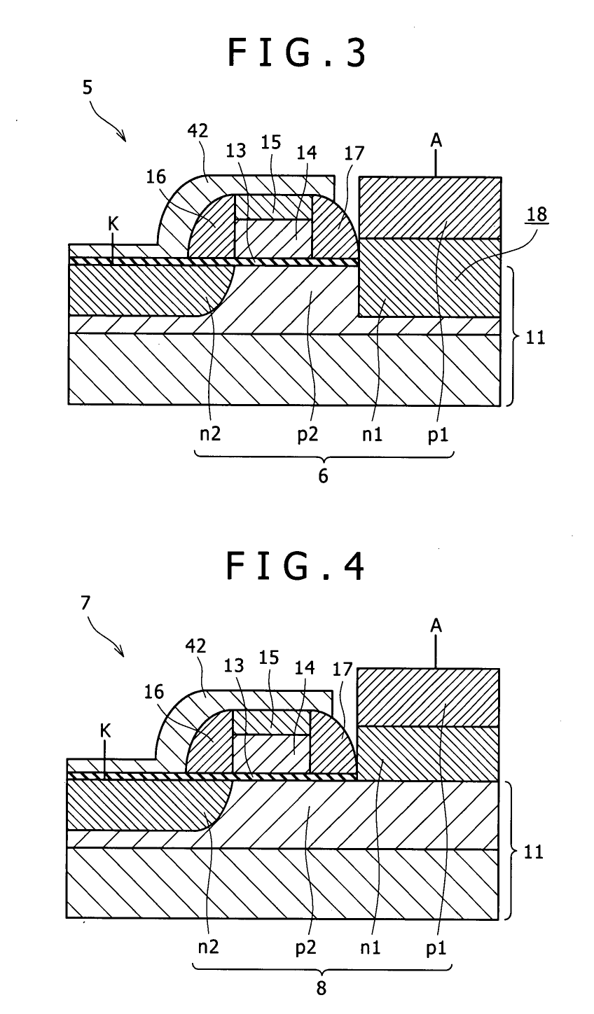

A semiconductor device according to one embodiment (third embodiment) of the present invention will be described below with reference to FIG. 3 as a sectional view of a schematic structure.

As shown in FIG. 3, a semiconductor device 5 includes a thyristor 6 arising from sequential joining of a first region (hereinafter, referred to as a first p-region) p1 of a first conductivity type (hereinafter, defined as the p-type), a second region (hereinafter, referred to as a first n-region) n1 of a second conductivity type (hereinafter, defined as the n-type) opposite to the first conductivity type, a third region (hereinafter, referred to as a second p-region) p2 of the first conductivity type (p-type), and a fourth region (hereinafter, referred to as a second n-region) n2 of the second conductivity type (n-type). Details of the semiconductor device 5 will be described below.

In a semiconductor substrate 11, the second p-region p2 of the first conductivity type (p-type) is formed. As this semiconductor substrate 11, e.g. a bulk silicon substrate is used. The second p-region p2 is formed by introducing, as a p-type dopant, e.g. boron (B) with a dopant concentration of about 5×10¹⁷ cm⁻³. It is desirable that the dopant concentration in the second p-region p2 be about 1×10¹⁶ cm⁻³ to 1×10¹⁹ cm⁻³. Basically, this dopant concentration should be lower than that in the first n-region n1 of the second conductivity type (n-type) to be described later. As the p-type dopant, besides boron (B), another p-type impurity such as indium (In) is available.

Over the second p-region p2, a gate electrode 14 is formed with the intermediary of a gate insulating film 13. An insulating film 15 serving as a hard mask may be formed over the gate electrode 14. The gate insulating film 13 is formed of e.g. a silicon oxide (SiO₂) film and has a thickness of about 1 nm to 10 nm. The material of the gate insulating film 13 is not limited to silicon oxide (SiO₂), but it is also possible to use silicon oxynitride (SiON) or use another gate insulating film material applicable to a typical CMOS transistor, such as hafnium oxide (HfO₂), hafnium oxynitride (HfON), aluminum oxide (Al₂O₃), hafnium silicate (HfSiO), nitrided hafnium silicate (HfSiON), or lanthanum oxide (La₂O₃).

The gate electrode 14 is generally formed of poly-crystalline silicon. It is also possible to employ a metal gate electrode as the gate electrode 14 or alternatively form the gate electrode 14 by using silicon germanium (SiGe) or the like. A hard mask used in the formation of the gate electrode 14 may be left over the gate electrode 14. This hard mask is formed of e.g. a silicon oxide (SiO₂) film, silicon nitride (Si₃N₄) film, or the like.

Sidewalls 16 and 17 are formed on the side faces of the gate electrode 14. These sidewalls 16 and 17 are formed of a silicon oxide (SiO₂) film, silicon nitride (Si₃N₄) film, or a multi-layer film of these films. An insulating film 42 is formed over the semiconductor substrate 11. Specifically, the insulating film 42 is formed over the area from a part of the gate electrode 14 to the side in which the region on one lateral side of the gate electrode 14 (second n-region n2) is formed. This insulating film 42 serves as a mask at the time of epitaxial growth, as described later in detail in the explanation of a manufacturing method.

In the second p-region p2 on one lateral side of the gate electrode 14, the first n-region n1 of the second conductivity type (n-type) is formed. The first n-region n1 is formed of a germanium layer or silicon germanium layer having a carrier mobility higher than that of silicon. The first n-region n1 is formed by epitaxially growing a germanium layer or silicon germanium layer in a recess 18 formed in the second p-region p2, and is formed by introducing e.g. phosphorous (P) as an n-type dopant to a dopant concentration of e.g. 1×10¹⁸ cm⁻³. It is desirable that this dopant concentration be about 1×10¹⁸ cm⁻³ to 1×10²⁰ cm⁻³, and this dopant concentration should be higher than that in the second p-region p2. Instead of phosphorous, another n-type dopant such as arsenic or antimony can also be used.

In the second p-region p2 on the other lateral side of the gate electrode 14, the second n-region n2 of the second conductivity type (n-type) is formed. This second n-region n2 is formed by introducing e.g. arsenic (As) as an n-type dopant to a dopant concentration of e.g. 5×10²⁰ cm⁻³. It is desirable that this dopant concentration be about 1×10¹⁸ cm⁻³ to 1×10²¹ cm⁻³, and this dopant concentration should be higher than that in the second p-region p2. Instead of arsenic, another n-type dopant such as phosphorous or antimony can also be used.

Furthermore, on the first n-region n1, the first p-region p1 of the first conductivity type (p-type) is formed by using e.g. an epitaxially grown silicon layer. The first p-region p1 is so formed that the concentration of boron (B) in the film is set to 1×10²⁰ cm⁻³ for example. It is desirable that this dopant (boron) concentration be about 1×10¹¹ cm⁻³ to 1×10²¹ cm⁻³.

An anode electrode A is connected to the first p-region p1, and a cathode electrode K is connected to the second n-region n2. Over the first p-region p1, the second n-region n2, and the gate electrode 14, a silicide (titanium silicide, cobalt silicide, nickel silicide, or the like) may be formed, although not shown in the drawing.

In the semiconductor device 5 in which the above-described thyristor 6 is used as a memory cell, a field effect transistor (not shown) may be formed as a selection transistor in the semiconductor substrate 11. Specifically, although not shown in the drawing, e.g. a well region of the first conductivity type (p-type) is formed in the semiconductor substrate 11, and the field effect transistor is formed by using this well region. For this field effect transistor, a gate electrode is formed over the p-type well region with the intermediary of a gate insulating film, and sidewalls are formed on both the sides of the gate electrode. Furthermore, in the p-type well region under the sidewalls, extension regions of the source and drain are formed. In addition, a drain region and a source region are formed in the p-type well region on one and the other lateral sides of the gate electrode with the intermediary of the extension region. The source region is connected to the second n-region n2 (cathode side) in the thyristor 6 via an interconnection (cathode electrode K). Furthermore, the drain region is connected to a bit line.

In the semiconductor device 5 according to an embodiment of the present invention, the first n-region n1 as the second region in the thyristor is, formed in a germanium layer or silicon germanium layer having mobility higher than that of silicon. Thus, the mobility of carriers in the first n-region n1 can be enhanced. This can increase the speed of sweeping of the carriers out of the first n-region n1, which can enhance the speed of switching from the on-state to the off-state. Furthermore, because the carrier mobility is enhanced, increase in the speed of switching from the off-state to the on-state can also be expected as a synergetic effect. It is generally known that the carrier mobility of germanium is higher than that of silicon. For example, the mobility of electrons and holes in silicon is 1600 cm²/V·s and 430 cm²/V·s, respectively. In contrast, the mobility of electrons and holes in germanium is 3900 cm²/V·s and 1900 cm²/V·s, respectively. That is, both the mobility of electrons and that of holes in germanium are higher, and in particular, the mobility of holes in germanium is as high as about five times that in silicon. Therefore, by using germanium or silicon germanium as the material of at least the first n-region n1, the switching speed of the thyristor 6 can be enhanced. This offers an advantage that the semiconductor device 5 having a high-speed thyristor can be provided.

A semiconductor device according to one embodiment (fourth embodiment) of the present invention will be described below with reference to FIG. 4 as a sectional view of a schematic structure.

As shown in FIG. 4, a semiconductor device 7 includes a thyristor 8 arising from sequential joining of a first region (hereinafter, referred to as a first p-region) p1 of a first conductivity type (hereinafter, defined as the p-type), a second region (hereinafter, referred to as a first n-region) n1 of a second conductivity type (hereinafter, defined as the n-type) opposite to the first conductivity type, a third region (hereinafter, referred to as a second p-region) p2 of the first conductivity type (p-type), and a fourth region (hereinafter, referred to as a second n-region) n2 of the second conductivity type (n-type). Details of the semiconductor device 7 will be described below.

In a semiconductor substrate 11, the second p-region p2 of the first conductivity type (p-type) is formed. As this semiconductor substrate 11, e.g. a bulk silicon substrate is used. The second p-region p2 is formed by introducing, as a p-type dopant, e.g. boron (B) with a dopant concentration of about 5×10¹⁷ cm⁻³. It is desirable that the dopant concentration in the second p-region p2 be about 1×10^{16 cm}⁻³ to 1×10¹⁹ cm⁻³. Basically, this dopant concentration should be lower than that in the first n-region n1 of the second conductivity type (n-type) to be described later. As the p-type dopant, besides boron (B), another p-type impurity such as indium (In) is available.

Over the second p-region p2, a gate electrode 14 is formed with the intermediary of a gate insulating film 13. An insulating film 15 serving as a hard mask may be formed over the gate electrode 14. The gate insulating film 13 is formed of e.g. a silicon oxide (SiO₂) film and has a thickness of about 1 nm to 10 nm. The material of the gate insulating film 13 is not limited to silicon oxide (SiO₂), but it is also possible to use silicon oxynitride (SiON) or use another gate insulating film material applicable to a typical CMOS transistor, such as hafnium oxide (HfO₂), hafnium oxynitride (HfON), aluminum oxide (Al₂O₃), hafnium silicate (HfSiO), nitrided hafnium silicate (HfSiON), or lanthanum oxide (La₂O₃).

The gate electrode 14 is generally formed of poly-crystalline silicon. It is also possible to employ a metal gate electrode as the gate electrode 14 or alternatively form the gate electrode 14 by using silicon germanium (SiGe) or the like. A hard mask used in the formation of the gate electrode 14 may be left over the gate electrode 14. This hard mask is formed of e.g. a silicon oxide (SiO₂) film, silicon nitride (Si₃N₄) film, or the like.

Sidewalls 16 and 17 are formed on the side faces of the gate electrode 14. These sidewalls 16 and 17 are formed of a silicon oxide (SiO₂) film, silicon nitride (Si₃N₄) film, or a multi-layer film of these films. An insulating film 42 is formed over the semiconductor substrate 11. Specifically, the insulating film 42 is formed over the area from a part of the gate electrode 14 to the side in which the region on one lateral side of the gate electrode 14 (second n-region n2) is formed. This insulating film 42 serves as a mask at the time of epitaxial growth, as described later in detail in the explanation of a manufacturing method. In addition, an insulating film 43 is formed over the semiconductor substrate 11. Specifically, the insulating film 43 is formed over the area from a part of the gate electrode 14 to the side in which the region on the other lateral side of the gate electrode 14 (first n-region n1) is formed. This insulating film 43 serves as a mask at the time of epitaxial growth of the first p-region p1, as described later in detail in the explanation of a manufacturing method.

On the second p-region p2 on one lateral side of the gate electrode 14, the first n-region n1 of the second conductivity type (n-type) is formed. The first n-region n1 is formed of a germanium layer or silicon germanium layer having a carrier mobility higher than that of silicon. The first n-region n1 is formed by epitaxially growing a germanium layer or silicon germanium layer, and is formed by introducing e.g. phosphorous (P) as an n-type dopant to a dopant concentration of e.g. 1×10¹⁸ cm⁻³. It is desirable that this dopant concentration be about 1×10¹⁸ cm⁻³ to 1×10²⁰ cm⁻³, and this dopant concentration should be higher than that in the second p-region p2. Instead of phosphorous, another n-type dopant such as arsenic or antimony can also be used.

In the second p-region p2 on the other lateral side of the gate electrode 14, the second n-region n2 of the second conductivity type (n-type) is formed. This second n-region n2 is formed by introducing e.g. arsenic (As) as an n-type dopant to a dopant concentration of e.g. 5×10²⁰ cm⁻³. It is desirable that this dopant concentration be about 1×10¹⁸ cm⁻³ to 1×10²¹ cm⁻³, and this dopant concentration should be higher than that in the second p-region p2. Instead of arsenic, another n-type dopant such as phosphorous or antimony can also be used.

Furthermore, on the first n-region n1, the first p-region p1 of the first conductivity type (p-type) is formed by using e.g. an epitaxially grown silicon layer. The first p-region p1 is so formed that the concentration of boron (B) in the film is set to 1×10²⁰ cm⁻³ for example. It is desirable that this dopant (boron) concentration be about 1×10¹⁸ cm⁻³ to 1×10²¹ cm⁻³.

An anode electrode A is connected to the first p-region p1, and a cathode electrode K is connected to the second n-region n2. Over the first p-region p1, the second n-region n2, and the gate electrode 14, a silicide (titanium silicide, cobalt silicide, nickel silicide, or the like) may be formed, although not shown in the drawing.

In the semiconductor device 7 in which the above-described thyristor 8 is used as a memory cell, a field effect transistor (not shown) may be formed as a selection transistor in the semiconductor substrate 11. Specifically, although not shown in the drawing, e.g. a well region of the first conductivity type (p-type) is formed in the semiconductor substrate 11, and the field effect transistor is formed by using this well region. For this field effect transistor, a gate electrode is formed over the p-type well region with the intermediary of a gate insulating film, and sidewalls are formed on both the sides of the gate electrode. Furthermore, in the p-type well region under the sidewalls, extension regions of the source and drain are formed. In addition, a drain region and a source region are formed in the p-type well region on one and the other lateral sides of the gate electrode with the intermediary of the extension region. The source region is connected to the second n-region n2 (cathode side) in the thyristor 8 via an interconnection (cathode electrode K). Furthermore, the drain region is connected to a bit line.

In the semiconductor device 7 according to an embodiment of the present invention, the first n-region n1 as the second region in the thyristor is formed in a germanium layer or silicon germanium layer having mobility higher than that of silicon. Thus, the mobility of carriers in the first n-region n1 can be enhanced. This can increase the speed of sweeping of the carriers out of the first n-region n1, which can enhance the speed of switching from the on-state to the off-state. Furthermore, because the carrier mobility is enhanced, increase in the speed of switching from the off-state to the on-state can also be expected as a synergetic effect. It is generally known that the carrier mobility of germanium is higher than that of silicon. For example, the mobility of electrons and holes in silicon is 1600 cm²/V·s and 430 cm²/V·s, respectively. In contrast, the mobility of electrons and holes in germanium is 3900 cm²/V·s and 1900 cm²/V·s, respectively. That is, both the mobility of electrons and that of holes in germanium are higher, and in particular, the mobility of holes in germanium is as high as about five times that in silicon. Therefore, by using germanium or silicon germanium as the material of at least the first n-region n1, the switching speed of the thyristor 8 can be enhanced. This offers an advantage that the semiconductor device 7 having a high-speed thyristor can be provided.

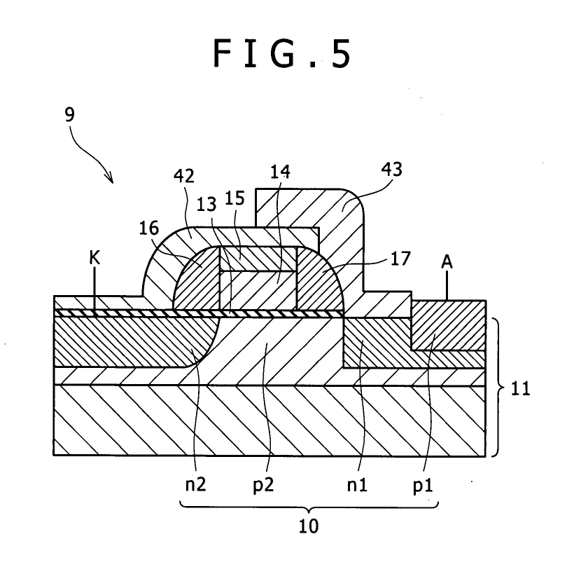

A semiconductor device according to one embodiment (fifth embodiment) of the present invention will be described below with reference to FIG. 5 as a sectional view of a schematic structure.

As shown in FIG. 5, a semiconductor device 9 includes a thyristor 10 arising from sequential joining of a first region (hereinafter, referred to as a first p-region) p1 of a first conductivity type (hereinafter, defined as the p-type), a second region (hereinafter, referred to as a first n-region) n1 of a second conductivity type (hereinafter, defined as the n-type) opposite to the first conductivity type, a third region (hereinafter, referred to as a second p-region) p2 of the first conductivity type (p-type), and a fourth region (hereinafter, referred to as a second n-region) n2 of the second conductivity type (n-type). Details of the semiconductor device 9 will be described below.

In a semiconductor substrate 11, the second p-region p2 of the first conductivity type (p-type) is formed. As this semiconductor substrate 11, e.g. a bulk silicon substrate is used. The second p-region p2 is formed by introducing, as a p-type dopant, e.g. boron (B) with a dopant concentration of about 5×10¹⁷ cm⁻³. It is desirable that the dopant concentration in the second p-region p2 be about 1×10¹⁶ cm⁻³ to 1×10¹⁹ cm⁻³. Basically, this dopant concentration should be lower than that in the first n-region n1 of the second conductivity type (n-type) to be described later. As the p-type dopant, besides boron (B), another p-type impurity such as indium (In) is available.

Over the second p-region p2, a gate electrode 14 is formed with the intermediary of a gate insulating film 13. An insulating film 15 serving as a hard mask may be formed over the gate electrode 14. The gate insulating film 13 is formed of e.g. a silicon oxide (SiO₂) film and has a thickness of about 1 nm to 10 nm. The material of the gate insulating film 13 is not limited to silicon oxide (SiO₂), but it is also possible to use silicon oxynitride (SiON) or use another gate insulating film material applicable to a typical CMOS transistor, such as hafnium oxide (HfO₂), hafnium oxynitride (HfON), aluminum oxide (Al₂O₃), hafnium silicate (HfSiO), nitrided hafnium silicate (HfSiON), or lanthanum oxide (La₂O₃).

The gate electrode 14 is generally formed of poly-crystalline silicon. It is also possible to employ a metal gate electrode as the gate electrode 14 or alternatively form the gate electrode 14 by using silicon germanium (SiGe) or the like. A hard mask used in the formation of the gate electrode 14 may be left over the gate electrode 14. This hard mask is formed of e.g. a silicon oxide (SiO₂) film, silicon nitride (Si₃N₄) film, or the like.

Sidewalls 16 and 17 are formed on the side faces of the gate electrode 14. These sidewalls 16 and 17 are formed of a silicon oxide (SiO₂) film, silicon nitride (Si₃N₄) film, or a multi-layer film of these films. Over the area from the second region n1 to the gate electrode 14, a salicide block (not shown) used when a salicide process is carried out for the anode side and cathode side may be formed.

In the second p-region p2 on one lateral side of the gate electrode 14, the first n-region n1 of the second conductivity type (n-type) is formed. The first n-region n1 is formed of a germanium layer or silicon germanium layer having a carrier mobility higher than that of silicon. The first n-region n1 is formed by epitaxially growing a germanium layer or silicon germanium layer in a recess 18 formed in the second p-region p2, and introducing e.g. phosphorous (P) as an n-type dopant to a dopant concentration of e.g. 1×10¹⁸ cm⁻³. It is desirable that this dopant concentration be about 1×10¹⁸ cm⁻³ to 1×10²⁰ cm⁻³, and this dopant concentration should be higher than that in the second p-region p2. Instead of phosphorous, another n-type dopant such as arsenic or antimony can also be used.

In the second p-region p2 on the other lateral side of the gate electrode 14, the second n-region n2 of the second conductivity type (n-type) is formed. This second n-region n2 is formed by introducing e.g. arsenic (As) as an n-type dopant to a dopant concentration of e.g. 5×10²⁰ cm⁻³. It is desirable that this dopant concentration be about 1×10¹⁸ cm⁻³ to 1×10²¹ cm⁻³, and this dopant concentration should be higher than that in the second p-region p2. Instead of arsenic, another n-type dopant such as phosphorous or antimony can also be used.

Furthermore, in a recess 19 formed in the first n-region n1, the first p-region p1 of the first conductivity type (p-type) is formed by using e.g. an epitaxially grown silicon layer. The first p-region p1 is so formed that the concentration of boron (B) in the film is set to 1×10²⁰ cm⁻³, for example. It is desirable that this dopant (boron) concentration be about 1×10¹⁸ cm⁻³ to 1×10²¹ cm⁻³.

An anode electrode A is connected to the first p-region p1, and a cathode electrode K is connected to the second n-region n2. Over the first p-region p1, the second n-region n2, and the gate electrode 14, a silicide (titanium silicide, cobalt silicide, nickel silicide, or the like) may be formed, although not shown in the drawing.

In the semiconductor device 9 in which the above-described thyristor 10 is used as a memory cell, a field effect transistor (not shown) may be formed as a selection transistor in the semiconductor substrate 11. Specifically, although not shown in the drawing, e.g. a well region of the first conductivity type (p-type) is formed in the semiconductor substrate 11, and the field effect transistor is formed by using this well region. For this field effect transistor, a gate electrode is formed over the p-type well region with the intermediary of a gate insulating film, and sidewalls are formed on both the sides of the gate electrode. Furthermore, in the p-type well region under the sidewalls, extension regions of the source and drain are formed. In addition, a drain region and a source region are formed in the p-type well region on one and the other lateral sides of the gate electrode with the intermediary of the extension region. The source region is connected to the second n-region n2 (cathode side) in the thyristor 10 via an interconnection (cathode electrode K). Furthermore, the drain region is connected to a bit line.

In the semiconductor device 9 according to an embodiment of the present invention, the first n-region n1 as the second region in the thyristor is formed in a germanium layer or silicon germanium layer having mobility higher than that of silicon. Thus, the mobility of carriers in the first n-region n1 can be enhanced. This can increase the speed of sweeping of the carriers out of the first n-region n1, which can enhance the speed of switching from the on-state to the off-state. Furthermore, because the carrier mobility is enhanced, increase in the speed of switching from the off-state to the on-state can also be expected as a synergetic effect. It is generally known that the carrier mobility of germanium is higher than that of silicon. For example, the mobility of electrons and holes in silicon is 1600 cm²/V·s and 430 cm²/V·s, respectively. In contrast, the mobility of electrons and holes in germanium is 3900 cm²/V·s and 1900 cm²/V·s, respectively. That is, both the mobility of electrons and that of holes in germanium are higher, and in particular, the mobility of holes in germanium is as high as about five times that in silicon. Therefore, by using germanium or silicon germanium as the material of at least the first n-region n1, the switching speed of the thyristor 10 can be enhanced. This offers an advantage that the semiconductor device 9 having a high-speed thyristor can be provided.

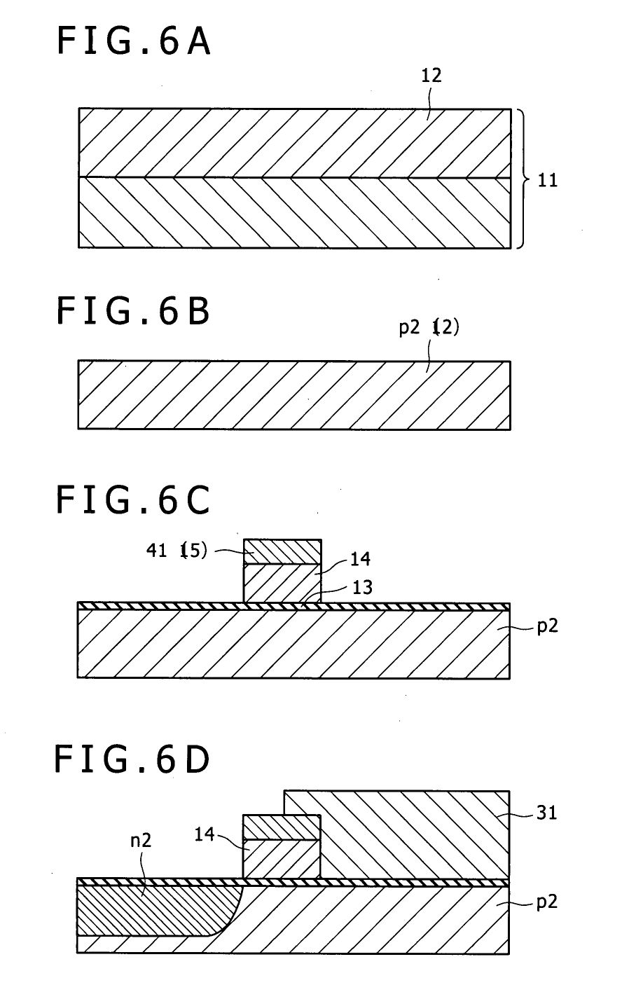

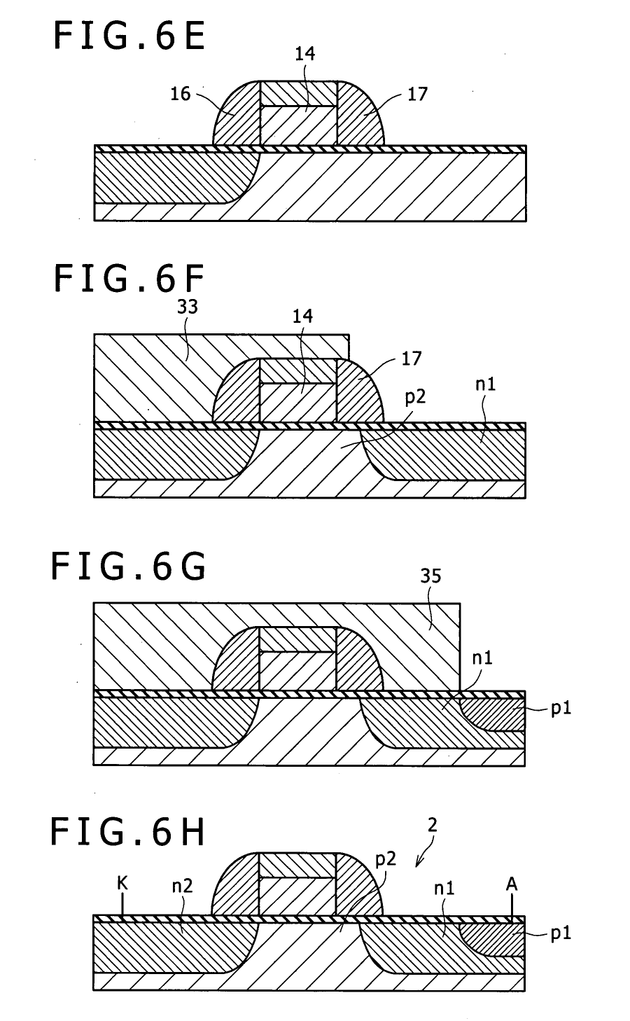

A method for manufacturing a semiconductor device according to one embodiment (first embodiment) of the present invention will be described below with reference to FIGS. 6A to 6H as sectional views of manufacturing steps. This manufacturing method is one example of a method for manufacturing the semiconductor device 1 described with FIG. 1.

Referring initially to FIG. 6A, e.g. a silicon substrate is used as the semiconductor substrate 11. Specifically, e.g. a bulk silicon substrate such as a CZ silicon wafer is used. Over the semiconductor substrate 11, the germanium layer 12 or silicon germanium layer having mobility higher than that of silicon is formed by e.g. epitaxial growth. As one example of the condition of the epitaxial growth, germane (GeH₄) is used as the source gas, and the deposition temperature is set to e.g. 700° C. The film thickness of the germanium layer 12 is so designed depending on the depth of the junction between the second p-region p2 as the third region and the first n-region n1, which will be formed later, that the lower face of the germanium layer 12 is disposed at a position deeper than the junction. It is also preferable to form a silicon germanium layer (not shown) as a buffer layer for lattice matching between the semiconductor substrate 11 formed of a silicon substrate and the germanium layer 12. Moreover, a silicon cap layer (not shown) may be deposited over the germanium layer 12. The purpose of the deposition of the silicon cap layer is to suppress reaction of the germanium layer, which is very highly reactive, and to obtain, in a later step of forming a gate insulating film and so on, the same film thickness of an oxide layer as that of an oxide layer formed on silicon. In FIG. 6B and the subsequent drawings, illustration of the semiconductor substrate 11 is omitted.

Referring next to FIG. 6B, the germanium layer 12 is turned into a region of the first conductivity type (p-type). This p-region will serve as the second p-region p2 of a thyristor. As one example of the condition of the ion implantation, boron (B) is used as a p-type dopant, and the dose amount is so set that a dopant concentration of 5×10¹⁷ cm⁻³ is obtained. It is desirable that this dopant concentration be about 1×10¹⁶ cm⁻³ to 1×10¹⁹ cm⁻³. Basically, this dopant concentration should be lower than that in the first n-region of the second conductivity type (n-type) to be formed later. As the p-type dopant, besides boron (B), another p-type dopant such as indium (In) is available. Alternatively, at the time of the formation of an epitaxial layer as the germanium layer 12, the epitaxial growth accompanied by addition of diborane (B₂H₆) may be carried out.

Referring next to FIG. 6C, the gate insulating film 13 is formed over the second p-region p2. This gate insulating film 13 is formed of e.g. a silicon oxide (SiO₂) film and deposited to a thickness of about 1 nm to 10 nm. The material of the gate insulating film 13 is not limited to silicon-oxide (SiO₂), but it is also possible to use silicon oxynitride (SiON) or use another gate insulating film material presently studied for a typical CMOS, such as hafnium oxide (HfO₂), hafnium oxynitride (HfON), aluminum oxide (Al₂O₃), hafnium silicate (HfSiO), nitrided hafnium silicate (HfSiON), or lanthanum oxide (La₂O₃).

Subsequently, the gate electrode 14 is formed on the gate insulating film 13 over the region that is to serve as the second p-region p2. The gate electrode 14 is generally formed of poly-crystalline silicon. It is also possible to employ a metal gate electrode as the gate electrode 14 or alternatively form the gate electrode 14 by using silicon germanium (SiGe) or the like.

The gate electrode 14 is formed in the following manner for example. Specifically, a gate electrode forming film is deposited on the gate insulating film 13, and then an etching mask is formed through typical resist application and lithography. Subsequently, by an etching technique with use of the etching mask, the gate electrode forming film is etch-processed. As this etching technique, general dry etching can be used. Alternatively, it is also possible to form the gate electrode 14 by wet etching. Furthermore, over the gate electrode forming film, a silicon oxide (SiO₂) film, silicon nitride (Si₃N₄) film, or the like may be formed as a hard mask 41 (insulating film 15).

Referring next to FIG. 6D, by typical resist application and lithography, an ion implantation mask 31 is formed in which an aperture is formed over the region on one lateral side of the gate electrode 14, i.e., over the region in which the second n-region is to be formed. Subsequently, by ion implantation with use of the ion implantation mask 31, an n-type dopant is introduced into the second p-region p2 formed on one lateral side of the gate electrode 14 to thereby form the second n-region n2. As an example of the condition of the ion implantation, phosphorous (P) is used as a dopant, and the dose amount is so set that a dopant concentration of 5×10²⁰ cm⁻³ is obtained. It is desirable that this dopant concentration be about 1×10¹⁸ cm⁻³ to 1×10²¹ cm⁻³, and this dopant concentration should be higher than that in the second p-region p2. Instead of phosphorous, another n-type dopant such as gallium, arsenic or antimony can also be used. After the ion implantation, the ion implantation mask 31 is removed.

Subsequently, as activation annealing, e.g. spike annealing at 1050° C. for about zero seconds is carried out. The conditions of this annealing may be any as long as the dopants can be activated.

Referring next to FIG. 6E, the sidewalls 16 and 17 are formed on the side faces of the gate electrode 14. These sidewalls 16 and 17 can be formed by depositing a sidewall forming film that covers the gate electrode 14 and then etching back this sidewall forming film, for example. The sidewalls 16 and 17 may be formed of either one of a silicon oxide (SiO₂) film and silicon nitride (Si₃N₄) film, or alternatively may be formed of a multi-layer film of these films. The sidewalls may be formed before the ion implantation step for forming the second n-region.

Referring next to FIG. 6F, by typical resist application and lithography, an ion implantation mask 33 is formed in which an aperture is formed over the region on the other lateral side of the gate electrode 14, i.e., over the region in which the first n-region is to be formed. Subsequently, by ion implantation with use of the ion implantation mask 33, a dopant of the second conductivity type (n-type) is introduced into the second p-region p2 positioned on the other lateral side of the gate electrode 14 with the intermediary of the sidewall 17, to thereby form the first n-region n1 of the second conductivity type (n-type). As an example of the condition of the ion implantation, phosphorous (P) is used as a dopant, and the dose amount is so set that a dopant concentration of 1.5×10¹⁹ cm⁻³ is obtained. It is desirable that this dopant concentration be about 1×10¹⁸ cm⁻³ to 1×10²⁰ cm⁻³, and this dopant concentration should be higher than that in the second p-region p2. Instead of phosphorous, another n-type dopant such as gallium, arsenic or antimony can also be used. After the ion implantation, the ion implantation mask 33 is removed.

Subsequently, as activation annealing, e.g. spike annealing at 1050° C. for about zero seconds is carried out. The conditions of this annealing may be any as long as the dopants can be activated.

Referring next to FIG. 6G, by typical resist application and lithography, an ion implantation mask 35 is formed in which an aperture is formed over the region in the first n-region n1 in which the first p-region is to be formed. Subsequently, by ion implantation with use of the ion implantation mask 35, a p-type dopant is introduced into an upper part of the first n-region n1 to thereby form the first p-region p1. As an example of the condition of the ion implantation, boron (B) is used as a dopant, and the dose amount is so set that a dopant concentration of 1×10²⁰ cm⁻³ is obtained. It is desirable that this dopant concentration be about 1×10¹⁸ cm⁻³ to 1×10²¹ cm⁻³, and this dopant concentration should be higher than that in the first n-region n1. The sidewalls may be formed before the ion implantation. The dopant may be another p-type impurity such as indium (In) or aluminum (Al). After the ion implantation, the ion implantation mask 35 is removed.

Subsequently, as activation annealing, e.g. spike annealing at 1000° C. for about zero seconds is carried out. The conditions of this annealing may be any as long as the dopants can be activated.

Referring next to FIG. 6H, by a typical electrode formation technique, the anode electrode A connected to the first p-region p1 and the cathode electrode K connected to the second n-region n2 are formed. At this time, it is preferable to form a silicide (TiSi, CoSi, NiSi, or the like) at the both-end electrode formation parts on the first p-region p1 and the second n-region n2 through a salicide step. In this case, it is preferable to form a salicide block covering the first n-region n1. After the electrode formation, a wiring step similar to that in a typical CMOS step is carried out.

In the manufacturing method of the first embodiment, the first n-region n1 in the thyristor is formed by using the germanium layer 12 or silicon germanium layer having mobility higher than that of silicon. Thus, the mobility of carriers in the first n-region n1 can be enhanced. This can increase the speed of sweeping of the carriers out of the first n-region n1, which can enhance the speed of switching from the on-state to the off-state. Furthermore, because the carrier mobility is enhanced, increase in the speed of switching from the off-state to the on-state can also be expected as a synergetic effect. It is generally known that the carrier mobility of germanium is higher than that of silicon. For example, the mobility of electrons and holes in silicon is 1600 cm²/V·s and 430 cm²/V·s, respectively. In contrast, the mobility of electrons and holes in germanium is 3900 cm²/V·s and 1900 cm²/V·s, respectively. That is, both the mobility of electrons and that of holes in germanium are higher, and in particular, the mobility of holes in germanium is as high as about five times that in silicon. Therefore, by using germanium or silicon germanium, which is a mixture of silicon and germanium with high carrier mobility, as the material of at least the second region, the switching speed of one thyristor 2 formed of the first p-region p1, the first n-region n1, the second p-region p2, and the second n-region n2 can be enhanced. This offers an advantage that a semiconductor device having the high-speed thyristor 2 can be manufactured.

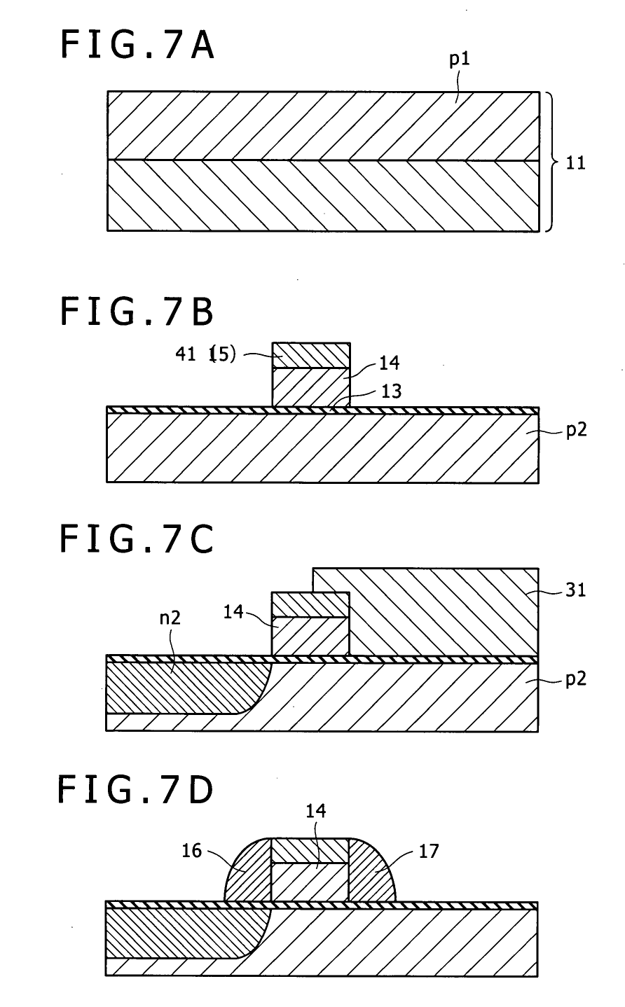

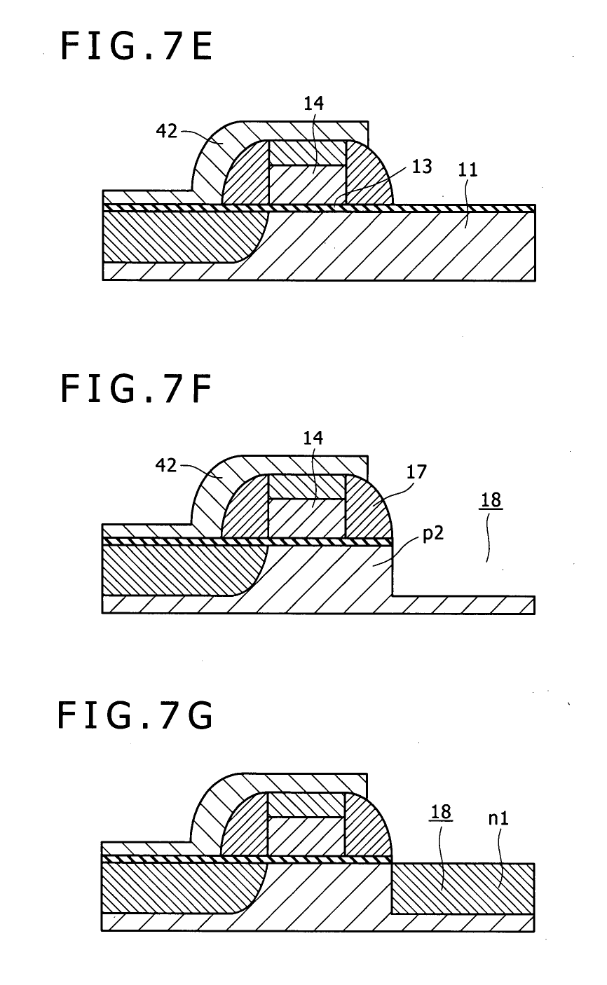

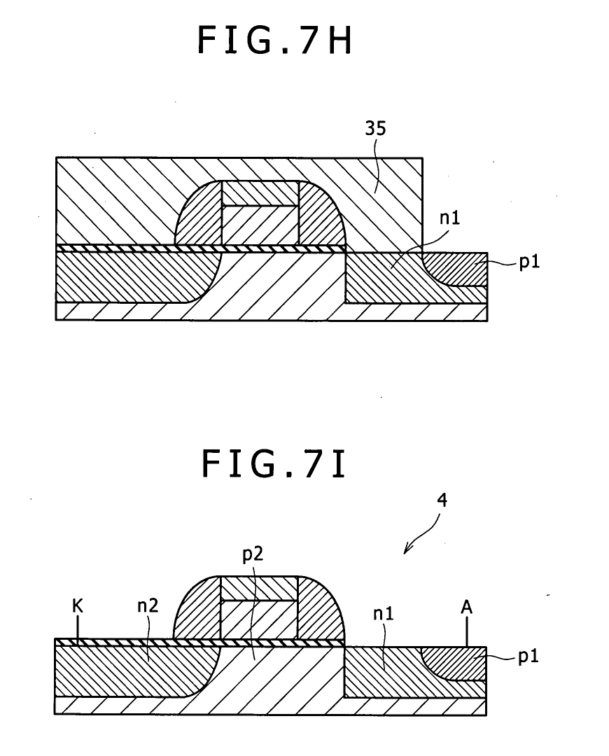

A method for manufacturing a semiconductor device according to one embodiment (second embodiment) of the present invention will be described below with reference to FIGS. 7A to 7I as sectional views of manufacturing steps. This manufacturing method is one example of a method for manufacturing the semiconductor device 3 described with FIG. 2.

Referring initially to FIG. 7A, e.g. a silicon substrate is used as the semiconductor substrate 11. Specifically, e.g. a bulk silicon substrate such as a CZ silicon wafer is used. A region of the first conductivity type (p-type) is formed in an upper part of the semiconductor substrate 11. This p-region will serve as the second p-region p2 of a thyristor. As one example of the condition of the ion implantation, boron (B) is used as a p-type dopant, and the dose amount is so set that a dopant concentration of 5×10¹⁷ cm⁻³ is obtained. It is desirable that this dopant concentration be about 1×10¹⁶ cm⁻³ to 1×10¹⁹ cm⁻³; Basically, this dopant concentration should be lower than that in the first n-region of the second conductivity type (n-type) to be formed later. As the p-type dopant, besides boron (B), another p-type dopant such as indium (In) is available. Alternatively, at the time of the formation of an epitaxial layer as the germanium layer 12, the epitaxial growth accompanied by addition of diborane (B₂H₆) may be carried out. In FIG. 7B and the subsequent drawings, illustration of a lower part of the semiconductor substrate 11 is omitted.

Referring-next to FIG. 7B, the gate insulating film 13 is formed over the second p-region p2. This gate insulating film 13 is formed of e.g. a silicon oxide (SiO₂) film and deposited to a thickness of about 1 nm to 10 nm. The material of the gate insulating film 13 is not limited to silicon oxide (SiO₂), but it is also possible to use silicon oxynitride (SiON) or use another gate insulating film material presently studied for a typical CMOS, such as hafnium oxide (HfO₂), hafnium oxynitride (HfON), aluminum oxide (Al₂O₃), hafnium silicate (HfSiO), nitrided hafnium silicate (HfSiON), or lanthanum oxide (La₂O₃).

Subsequently, the gate electrode 14 is formed on the gate insulating film 13 over the region that is to serve as the second p-region p2. The gate electrode 14 is generally formed of poly-crystalline silicon. It is also possible to employ a metal gate electrode as the gate electrode 14 or alternatively form the gate electrode 14 by using silicon germanium (SiGe) or the like.

The gate electrode 14 is formed in the following manner, for example. Specifically, a gate electrode forming film is deposited on the gate insulating film 13, and then an etching mask is formed through typical resist application and lithography. Subsequently, by an etching technique with use of the etching mask, the gate electrode forming film is etch-processed. As this etching technique, general dry etching can be used. Alternatively, it is also possible to form the gate electrode 14 by wet etching. Furthermore, over the gate electrode forming film, a silicon oxide (SiO₂) film, silicon nitride (Si₃N₄) film, or the like may be formed as a hard mask 41 (insulating film 15).

Referring next to FIG. 7C, by typical resist application and lithography, an ion implantation mask 31 is formed in which an aperture is formed over the region on one lateral side of the gate electrode 14, i.e., over the region in which the second n-region is to be formed. Subsequently, by ion implantation with use of the ion implantation mask 31, an n-type dopant is introduced into the second p-region p2 formed on one lateral side of the gate electrode 14 to thereby form the second n-region n2. As an example of the condition of the ion implantation, phosphorous (P) is used as a dopant, and the dose amount is so set that a dopant concentration of 5×10²⁰ cm⁻³ is obtained. It is desirable that this dopant concentration be about 1×10¹⁸ cm⁻³ to 1×10²⁰ cm⁻³, and this dopant concentration should be higher than that in the second p-region p2. Instead of phosphorous, another n-type dopant such as gallium, arsenic or antimony can also be used. After the ion implantation, the ion implantation mask 31 is removed.

Subsequently, as activation annealing, e.g. spike annealing at 1050° C. for about zero seconds is carried out. The conditions of this annealing may be any as long as the dopants can be activated.

Referring next to FIG. 7D, the sidewalls 16 and 17 are formed on the side faces of the gate electrode 14. These sidewalls 16 and 17 can be formed by depositing a sidewall forming film that covers the gate electrode 14 and then etching back this sidewall forming film, for example. The sidewalls 16 and 17 may be formed of either one of a silicon oxide (SiO₂) film and silicon nitride (Si₃N₄) film, or alternatively may be formed of a multi-layer film of these films. The sidewalls may be formed before the ion implantation step for forming the second n-region.

Referring next to FIG. 7E, the insulating film 42 that is to serve as a mask at the time of epitaxial growth is formed. This insulating film 42 is formed of e.g. a silicon nitride film. The film thickness thereof is set to e.g. 20 nm. Thereafter, by typical resist application and lithography, an etching mask (not shown) is formed in which an aperture is formed over the region on the other lateral side of the gate electrode 14, i.e., over the region in which the first n-region is to be formed. Subsequently, by an etching technique with use of this etching mask, the insulating film 42 on the other lateral side of the gate electrode 14 is etched. In this etching, the gate insulating film 13 in the etching area may be etched. This etching exposes the surface of the semiconductor substrate 11 in the region in which the first n-region is to be formed. In this example, a silicon nitride film is used in order to ensure the selectivity at the time of the epitaxial growth. However, another kind of film may be used as long as the selectivity can be ensured. Furthermore, this step may be carried out simultaneously with the sidewall forming step.

Referring next to FIG. 7F, the recess 18 is formed by etching the second p-region p2 with use of the insulating film 42 and the sidewall 17 as the mask. At this time, if the gate insulating film 13 remains, this gate insulating film 13 is removed through the etching. This recess 18 is formed by etching the semiconductor substrate 11 to a depth of e.g. 200 nm. This etching depth is equivalent to the depth of the junction between the first n-region n1 and the second p-region p2, and therefore, may be adequately changed depending on device characteristics.

Referring next to FIG. 7G, the first n-region n1 of the second conductivity type (n-type) is formed in the recess 18 by epitaxial growth. This first n-region n1 is formed by using selective epitaxial growth of germanium or silicon germanium. As one example of the condition of this epitaxial growth, germane (GeH₄), phosphine (PH₃), and hydrogen chloride (HCl) gas are used as the source gas, and the substrate temperature (deposition temperature) is set to 750° C. Furthermore, the condition is so set that a dopant concentration (e.g., phosphorous concentration) of e.g. 1×10¹⁸ cm⁻³ is obtained. It is desirable that this dopant concentration be about 1×10¹⁸ cm⁻³ to 1×10²¹ cm⁻³. Instead of phosphine (PH₃), another n-type impurity source such as arsine (AsH₃) or an organic source of any of these substances may be used. Thereafter, the ion implantation mask 33 is removed. Before the epitaxial growth, the surface of the silicon substrate may be cleaned by using a chemical such as hydrof luoric acid (HF), hydrogen (H₂) gas, and so on according to need.

Referring next to FIG. 7H, by typical resist application and lithography, an ion implantation mask 35 is formed in which an aperture is formed over the region in the first n-region n1 in which the first p-region is to be formed. Subsequently, by ion implantation with use of the ion implantation mask 35, a p-type dopant is introduced into an upper part of the first n-region n1 to thereby form the first p-region p1. As an example of the condition of the ion implantation, boron (B) is used as a dopant, and the dose amount is so set that a dopant concentration of 1×10²⁰ cm⁻³ is obtained. It is desirable that this dopant concentration be about 1×10¹⁸ cm⁻³ to 1×10²¹ cm⁻³, and this dopant concentration should be higher than that in the first n-region n1. The sidewalls may be formed before the ion implantation. The dopant may be another p-type impurity such as indium (In) or aluminum (Al). After the ion implantation, the ion implantation mask 35 is removed.

Subsequently, as activation annealing, e.g. spike annealing at 1000° C. for about zero seconds is carried out. The conditions of this annealing may be any as long as the dopants can be activated.

Referring next to FIG. 7I, by a typical electrode formation technique, the anode electrode A connected to the first p-region p and the cathode electrode K connected to the second n-region n2 are formed. At this time, it is preferable to form a silicide (TiSi, CoSi, NiSi, or the like) at the both-end exposed parts on the first p-region p1 and the second n-region n2 through a salicide step. After the electrode formation, a wiring step similar to that in a typical CMOS step is carried out.

In the manufacturing method of the second embodiment, the first n-region n1 in the thyristor 4 is formed by using a germanium layer or silicon germanium layer having mobility higher than that of silicon. Thus, the mobility of carriers in the first n-region n1 can be enhanced. This can increase the speed of sweeping of the carriers out of the first n-region n1, which can enhance the speed of switching from the on-state to the off-state. Furthermore, because the carrier mobility is enhanced, increase in the speed of switching from the off-state to the on-state can also be expected as a synergetic effect. It is generally known that the carrier mobility of germanium is higher than that of silicon. For example, the mobility of electrons and holes in silicon is 1600 cm²/V·s and 430 cm²/V·s, respectively. In contrast, the mobility of electrons and holes in germanium is 3900 cm²/V·s and 1900 cm²/V·s, respectively. That is, both the mobility of electrons and that of holes in germanium are higher, and in particular, the mobility of holes in germanium is as high as about five times that in silicon. Therefore, by using germanium or silicon germanium, which is a mixture of silicon and germanium with high carrier mobility, as the material of at least the second region, the switching speed of the thyristor 4 formed of the first p-region p1, the first n-region n1, the second p-region p2, and the second n-region n2 can be enhanced. This offers an advantage that the semiconductor device 3 having the high-speed thyristor 4 can be manufactured.

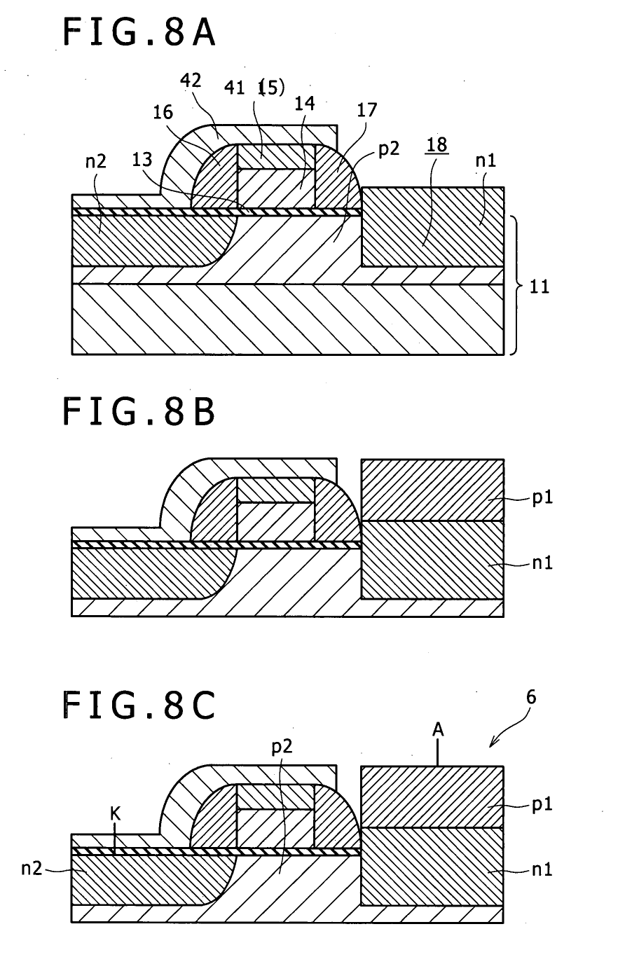

A method for manufacturing a semiconductor device according to one embodiment (third embodiment) of the present invention will be described below with reference to FIGS. 8A to 8C as sectional views of manufacturing steps. This manufacturing method is one example of a method for manufacturing the semiconductor device 3 described with FIG. 3.

The steps described with FIGS. 7A to 7F are carried out. These steps described with FIGS. 7A to 7F are the same as those in the manufacturing method of the second embodiment, and therefore, the description thereof is omitted. As the result of the steps, as shown in FIG. 8A, the second p-region p2 is formed in the semiconductor substrate 11, and the gate electrode 14 is formed over the second p-region p2 with the intermediary of the gate insulating film 13. The hard mask 41 is formed on the gate electrode 14. The sidewalls 16 and 17 are formed on the side faces of the gate electrode 14, and the second n-region n2 is formed in the second p-region p2 on one lateral side of the gate electrode 14. Subsequently, the insulating film 42 that is to serve as a mask at the time of epitaxial growth is formed. This insulating film 42 is formed of e.g. a silicon nitride film. The film thickness thereof is set to e.g. 20 nm. Thereafter, by typical resist application and lithography, an etching mask (not shown) is formed in which an aperture is formed over the region on the other lateral side of the gate electrode 14, i.e., over the region in which the first n-region is to be formed. Subsequently, by an etching technique with use of this etching mask, the insulating film 42 on the other lateral side of the gate electrode 14 is etched to thereby expose the surface of the semiconductor substrate 11 in the region in which the first n-region is to be formed. The recess 18 is formed by etching the second p-region p2 with use of the insulating film 42 and the sidewall 17 as the mask. Subsequently, the first n-region n1 of the second conductivity type (n-type), composed of germanium or silicon germanium, is formed in the recess 18 by selective epitaxial growth. This first n-region n1 is so formed that the upper face thereof is higher than the surface of the semiconductor substrate (silicon substrate) 11 by about 50 nm to 100 nm. This can prevent the short-circuit between the second p-region p2 and the first p-region p1 to be formed later.

As one example of the condition of this selective epitaxial growth, germane (GeH₄), phosphine (PH₃), and hydrogen chloride (HCl) gas are used as the source gas, and the substrate temperature (deposition temperature) is set to 750° C. Furthermore, the condition is so set that a dopant concentration (e.g., phosphorous concentration) of e.g. 1×10¹⁸ cm⁻³ is obtained. It is desirable that this dopant concentration be about 1×10¹⁷ cm⁻³ to 1×10²¹ cm⁻³. Instead of phosphine (PH₃), another n-type impurity source such as arsine (AsH₃) or an organic source of any of these substances may be used. Before the epitaxial growth, the surface of the silicon substrate may be cleaned by using a chemical such as hydrofluoric acid (HF), hydrogen (H₂) gas, and so on according to need. In FIGS. 8B and 8C, illustration of a lower part of the semiconductor substrate 11 is omitted.

Referring next to FIG. 8B, the first p-region p1 of the first conductivity type (p-type), formed of an epitaxially grown silicon layer, is formed on the first n-region n1 by selective epitaxial growth. As one example of the condition of this selective epitaxial growth, monosilane (SiH₄), diborane (B₂H₆), and hydrogen chloride (HCl) gas are used as the source gas, and the substrate temperature (deposition temperature) is set to 750° C. Furthermore, the condition is so set that a dopant concentration (e.g., boron concentration) of e.g. 1×10²⁰ cm⁻³ is obtained. It is desirable that this dopant concentration be about 1×10¹⁸ cm⁻³ to 1×10²¹ cm⁻³. Instead of monosilane (SiH₄), disilane (Si₂H₆), trisilane (Si₃H₈), dichlorosilane (SiH₂Cl₂), trichlorosilane (SiHCl₃), tetrachlorosilane (SiCl₄), or the like may be used. Furthermore, instead of diborane (B₂H₆), another p-type impurity source such as an organic source may be used. In addition, a silicon germanium (SiGe) film may be deposited instead of the silicon (Si) film by selective epitaxial growth. However, because this film should have a band gap wider than that of germanium (Ge), the composition ratio of silicon (Si) to germanium (Ge) should be adequately adjusted.

After this film deposition, as activation annealing, e.g. spike annealing at 1000° C. for about zero seconds is carried out according to need. The conditions of this annealing may be any as long as the dopants can be activated. This activation annealing may be carried out after the first n-region n1 is formed.

Referring next to FIG. 8C, by a typical electrode formation technique, the anode electrode A connected to the first p-region p1 and the cathode electrode K connected to the second n-region n2 are respectively formed. At this time, it is preferable to form a silicide (TiSi, CoSi, NiSi, or the like) at the both-end exposed parts on the first p-region p1 and the second n-region n2 through a salicide step. After the electrode formation, a wiring step similar to that in a typical CMOS step is carried out.

In the manufacturing method of the third embodiment, the first n-region n1 in the thyristor 6 is formed by using a germanium layer or silicon germanium layer having mobility higher than that of silicon. Thus, the mobility of carriers in the first n-region n1 can be enhanced. This can increase the speed of sweeping of the carriers out of the first n-region n1, which can enhance the speed of switching from the on-state to the off-state. Furthermore, because the carrier mobility is enhanced, increase in the speed of switching from the off-state to the on-state can also be expected as a synergetic effect. It is generally known that the carrier mobility of germanium is higher than that of silicon. For example, the mobility of electrons and holes in silicon is 1600 cm²/V·s and 430 cm²/V·s, respectively. In contrast, the mobility of electrons and holes in germanium is 3900 cm²/V·s and 1900 cm²/V·s, respectively. That is, both the mobility of electrons and that of holes in germanium are higher, and in particular, the mobility of holes in germanium is as high as about five times that in silicon. Therefore, by using germanium or silicon germanium, which is a mixture of silicon and germanium with high carrier mobility, as the material of at least the second region, the switching speed of the thyristor 6 formed of the first p-region p1, the first n-region n1, the second p-region p2, and the second n-region n2 can be enhanced. This offers an advantage that the semiconductor device 5 having the high-speed thyristor 6 can be manufactured.

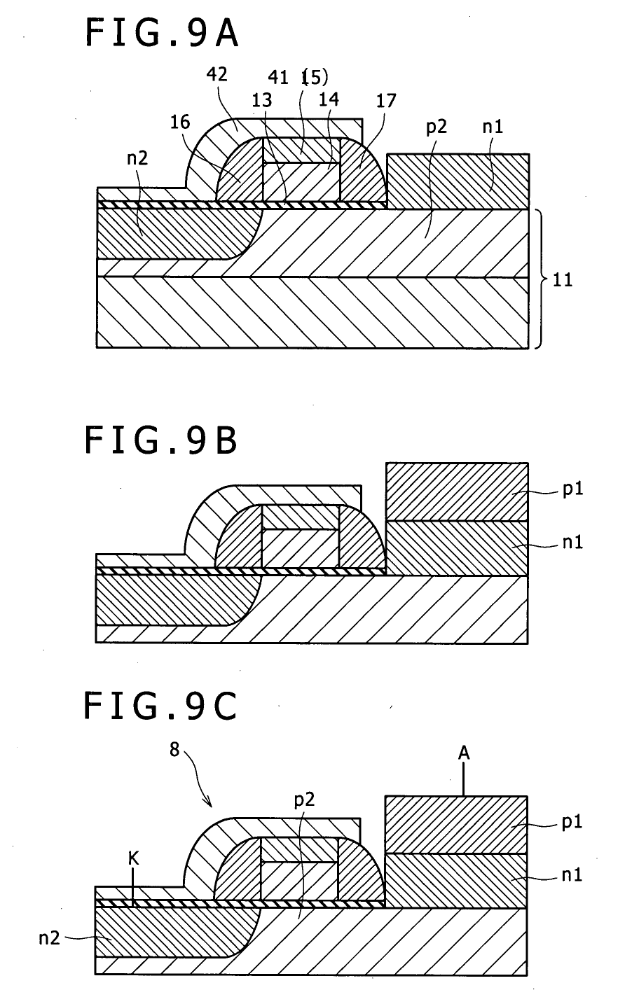

A method for manufacturing a semiconductor device according to one embodiment (fourth embodiment) of the present invention will be described below with reference to FIGS. 9A to 9C as sectional views of manufacturing steps. This manufacturing method is one example of a method for manufacturing the semiconductor device 7 described with FIG. 4.

The steps described with FIGS. 7A to 7E are carried out. These steps described with FIGS. 7A to 7E are the same as those in the manufacturing method of the second embodiment, and therefore, the description thereof is omitted. As the result of the steps, as shown in FIG. 9A, the second p-region p2 is formed in the semiconductor substrate 11, and the gate electrode 14 is formed over the second p-region p2 with the intermediary of the gate insulating film 13. The hard mask 41 (insulating film 15) is formed on the gate electrode 14. The sidewalls 16 and 17 are formed on the side faces of the gate electrode 14, and the second n-region n2 is formed in the second p-region p2 on one lateral side of the gate electrode 14. Subsequently, the insulating film 42 that is to serve as a mask at the time of epitaxial growth is formed. This insulating film 42 is formed of e.g. a silicon nitride film. The film thickness thereof is set to e.g. 20 nm. Thereafter, by typical resist application and lithography, an etching mask (not shown) is formed in which an aperture is formed over the region on the other lateral side of the gate electrode 14, i.e., over the region on which the first n-region is to be formed. Subsequently, by an etching technique with use of this etching mask, the insulating film 42 on the other lateral side of the gate electrode 14 is etched to thereby expose the surface of the semiconductor substrate 11 in the region on which the first n-region is to be formed. Subsequently, the first n-region n1 of the second conductivity type (n-type), composed of silicon germanium or germanium, is formed on the exposed semiconductor substrate 11 (second p-region p2) by selective epitaxial growth. In this example, the first n-region n1 is formed by using silicon germanium as one example.

As one example of the condition of this selective epitaxial growth, monosilane (SiH₄), germane (GeH₄), diborane (B₂H₆), phosphine (PH₃), and hydrogen chloride (HCl) gas are used as the source gas, and the substrate temperature (deposition temperature) is set to 750° C. Furthermore, the conditions are so set that a dopant concentration (e.g., phosphorpus concentration) of e.g. 1×10¹⁸ cm⁻³ is obtained. It is desirable that this dopant concentration be about 1×10¹⁷ cm⁻³ to 1×10²¹ cm⁻³. The film thickness of the first n-region n1 is set to e.g. 50 nm to 300 nm. In this example, the thickness is set to 100 nm as one example. In this epitaxial growth, the flow rate of monosilane (SiH₄) and germane (GeH₄) is changed in a continuous or step manner in such a way that a part closer to the surface of the silicon substrate will have a higher composition ratio of germanium (Ge) and the composition ratio of silicon. (Si) will become higher as the deposition progresses. This scheme can achieve continuous changes of the band gap, and thus makes it possible to generate a self electric field in the silicon germanium (SiGe) layer. As a result, carriers can be accelerated, which permits high-speed operation. Instead of monosilane (SiH₄), disilane (Si₂H₆), trisilane (Si₃H₈), dichlorosilane (SiH₂Cl₂), trichlorosilane (SiHCl₃), tetrachlorosilane (SiCl₄), or the like may be used. Instead of phosphine (PH₃), another n-type impurity source such as arsine (AsH₃) or an organic source of any of these substances may be used. Before the epitaxial growth, the surface of the silicon substrate may be cleaned by using a chemical such as hydrofluoric acid (HF), hydrogen (H₂) gas, and so on according to need. In FIGS. 9B and 9C, illustration of a lower part of the semiconductor substrate 11 is omitted.

Referring next to FIG. 9B, the first p-region p1 of the first conductivity type (p-type), formed of an epitaxially grown silicon layer, is formed on the first n-region n1 by selective epitaxial growth. As one example of the condition of this selective epitaxial growth, monosilane (SiH₄), diborane (B₂H₆), and hydrogen chloride (HCl) gas are used as the source gas, and the substrate temperature (deposition temperature) is set to 750° C. Furthermore, the conditions are so set that a dopant concentration (e.g., boron concentration) of e.g. 1×10²⁰ cm⁻³ is obtained. It is desirable that this dopant concentration be about 1×10¹⁸ cm⁻³ to 1×10²¹ cm⁻³. Instead of monosilane (SiH₄), disilane (Si₂H₆), trisilane (Si₃H₈), dichlorosilane (SiH₂Cl₂), trichlorosilane (SiHCl₃), tetrachlorosilane (SiCl₄), or the like may be used. Furthermore, instead of diborane (B₂H₆), another p-type impurity source such as an organic source may be used. In addition, a silicon germanium (SiGe) film may be deposited instead of the silicon (Si) film by selective epitaxial growth. However, because this film should have a band gap wider than that of the uppermost part of the n-type region (first n-region n1), the composition ratio of silicon (Si) to germanium (Ge) should be adequately adjusted.

After this film deposition, as activation annealing, e.g. spike annealing at 1000° C. for about zero seconds is carried out according to need. The conditions of this annealing may be any as long as the dopants can be activated. This activation annealing may be carried out after the first n-region n1 is formed.

Referring next to FIG. 9C, by a typical electrode formation technique, the anode electrode A connected to the first p-region p1 and the cathode electrode K connected to the second n-region n2 are formed. At this time, it is preferable to form a silicide (TiSi, CoSi, NiSi, or the like) at the both-end exposed parts on the first p-region p1 and the second n-region n2 through a salicide step. After the electrode formation, a wiring step similar to that in a typical CMOS step is carried out.

In the manufacturing method of the fourth embodiment, the first n-region n1 in the thyristor 8 is formed by using a germanium layer or silicon germanium layer having mobility higher than that of silicon. Thus, the mobility of carriers in the first n-region n1 can be enhanced. This can increase the speed of sweeping of the carriers out of the first n-region n1, which can enhance the speed of switching from the on-state to the off-state. Furthermore, because the carrier mobility is enhanced, increase in the speed of switching from the off-state to the on-state can also be expected as a synergetic effect. It is generally known that the carrier mobility of germanium is higher than that of silicon. For example, the mobility of electrons and holes in silicon is 1600 cm²/V·s and 430 cm²/V·s, respectively. In contrast, the mobility of electrons and holes in germanium is 3900 cm²/V·s and 1900 cm²/V·s, respectively. That is, both the mobility of electrons and that of holes in germanium are higher, and in particular, the mobility of holes in germanium is as high as about five times that in silicon. Therefore, by using germanium or silicon germanium, which is a mixture of silicon and germanium with high carrier mobility, as the material of at least the second region, the switching speed of the thyristor 8 formed of the first p-region p1, the first n-region n1, the second p-region p2, and the second n-region n2 can be enhanced. This offers an advantage that the semiconductor device 7 having the high-speed thyristor 8 can be manufactured.

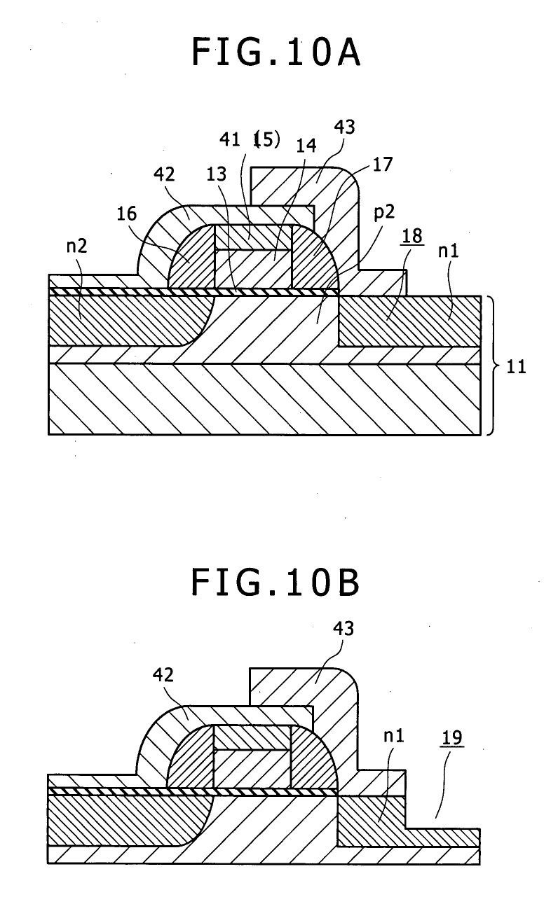

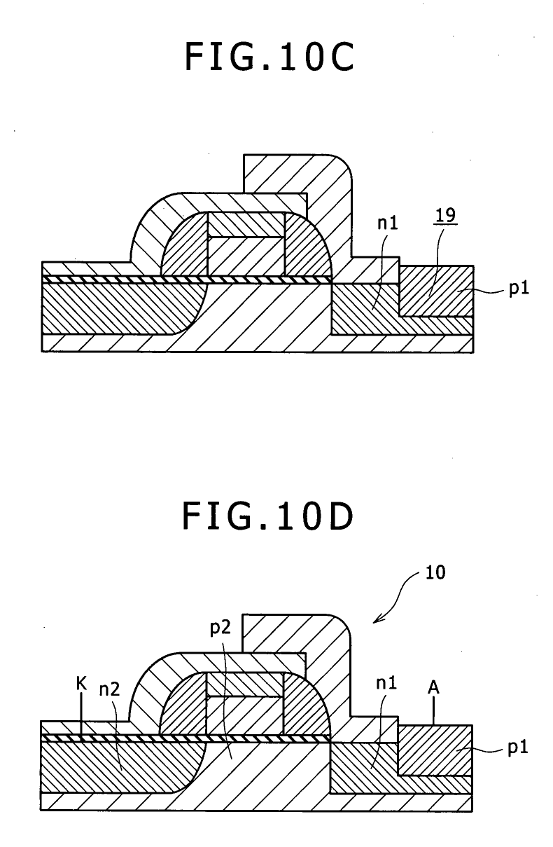

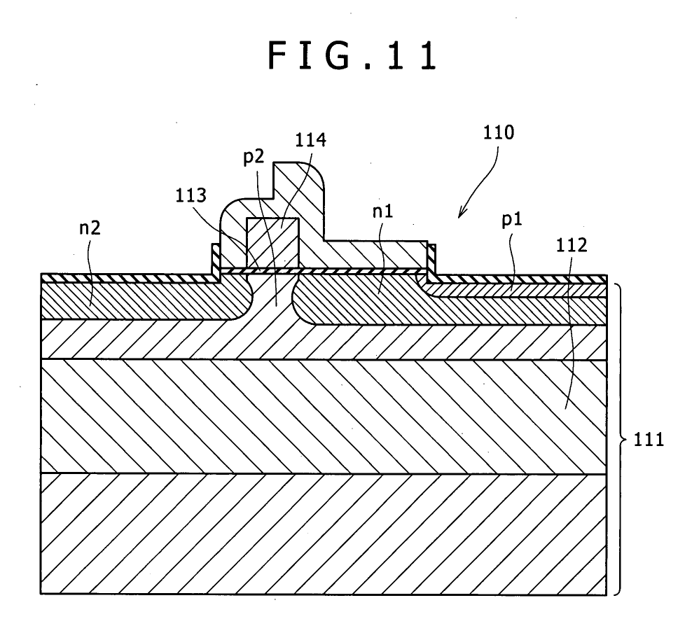

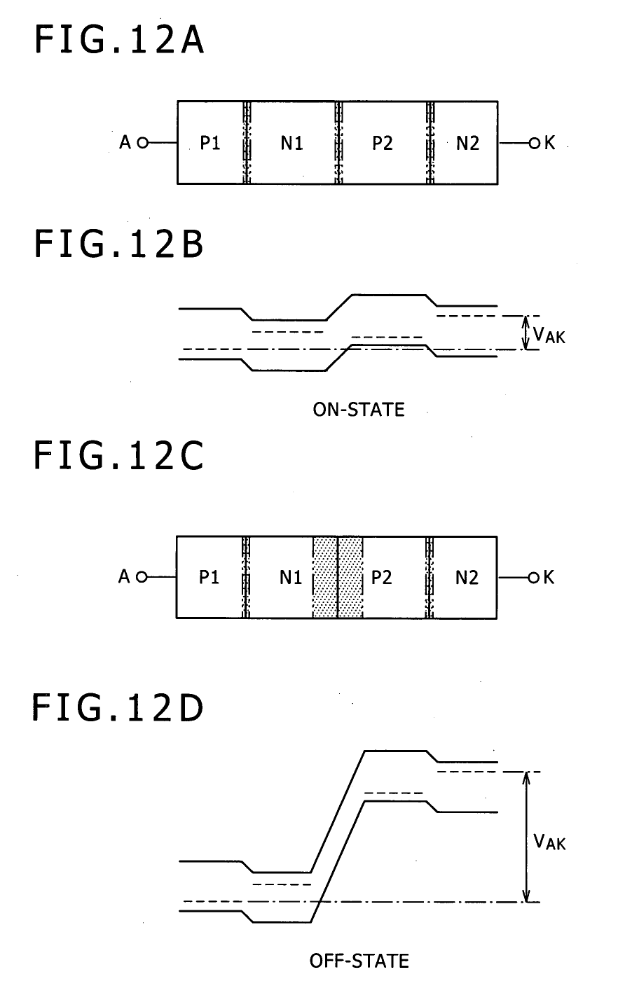

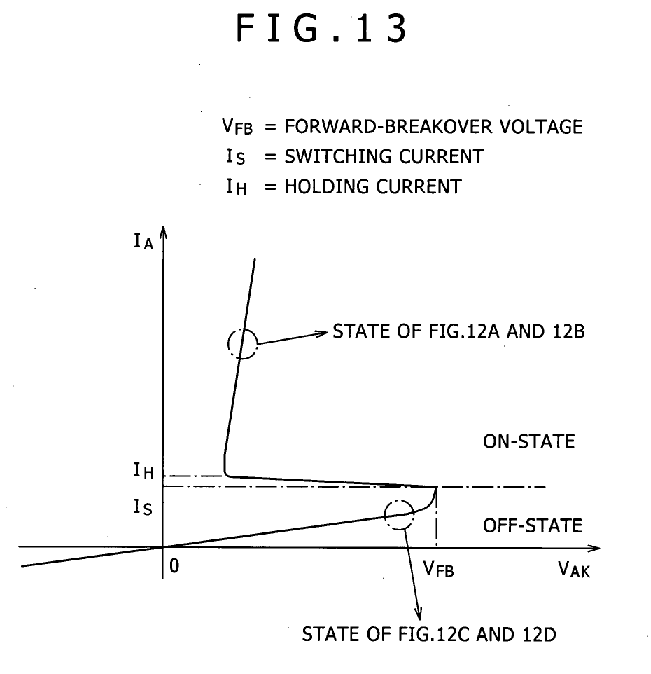

A method for manufacturing a semiconductor device according to one embodiment (fifth embodiment) of the present invention will be described below with reference to FIGS. 10A and 10D as sectional views of manufacturing steps. This manufacturing method is one example of a method for manufacturing the semiconductor device 9 described with FIG. 5.

The steps described with FIGS. 7A to 7G are carried out. These steps described with FIGS. 7A to 7G are the same as those in the manufacturing method of the second embodiment, and therefore, the description thereof is omitted. As the result of the steps, as shown in FIG. 10A, the second p-region p2 is formed in the semiconductor substrate 11, and the gate electrode 14 is formed over the second p-region p2 with the intermediary of the gate insulating film 13. The hard mask 41 (insulating film 15) is formed on the gate electrode 14. The sidewalls 16 and 17 are formed on the side faces of the gate electrode 14, and the second n-region n2 is formed in the second p-region p2 on one lateral side of the gate electrode 14. Subsequently, the insulating film 42 that is to serve as a mask at the time of epitaxial growth is formed. This insulating film 42 is formed of e.g. a silicon nitride film. The film thickness thereof is set to e.g. 20 nm. Thereafter, by typical resist application and lithography, an etching mask (not shown) is formed in which an aperture is formed over the region on the other lateral side of the gate electrode 14, i.e., over the region in which the first n-region is to be formed. Subsequently, by an etching technique with use of this etching mask, the insulating film 42 on the other lateral side of the gate electrode 14 is etched to thereby expose the surface of the semiconductor substrate 11 in the region in which the first n-region is to be formed. The recess 18 is formed by etching the second p-region p2 with use of the insulating film 42 and the sidewall 17 as the mask. Subsequently, the first n-region n1 of the second conductivity type (n-type), composed of germanium or silicon germanium, is formed in the recess 18 by selective epitaxial growth. This first n-region n1 is so formed that the upper face thereof is higher than the surface of the semiconductor substrate (silicon substrate) 11 by about 50 nm to 100 nm. This can prevent the short-circuit between the second p-region p2 and the first p-region p1 to be formed later.

As one example of the condition of this selective epitaxial growth, monosilane (SiH₄), germane (GeH₄), diborane (B₂H₆), phosphine (PH₃), and hydrogen chloride (HCl) gas are used as the source gas, and the substrate temperature (deposition temperature) is set to 750° C. Furthermore, the condition is so set that a dopant concentration (e.g., phosphorpus concentration) of e.g. 1×10¹⁸ cm⁻³ is obtained. It is desirable that this dopant concentration be about 1×10¹⁷ cm⁻³ to 1×10²¹ cm⁻³. The film thickness of the first n-region n1 is set to e.g. 50 nm to 300 nm. In this example, the thickness is set to 100 nm as one example. In this epitaxial growth, the flow rate of monosilane (SiH₄) and germane (GeH₄) is changed in a continuous or step manner in such a way that a part closer to the surface of the silicon substrate will have a higher composition ratio of germanium (Ge) and the composition ratio of silicon (Si) will become higher as the deposition progresses. This scheme can achieve continuous changes of the band gap, and thus makes it possible to generate a self electric field in the silicon germanium (SiGe) layer. As a result, carriers can be accelerated, which permits high-speed operation. Instead of monosilane (SiH₄), disilane (Si₂H₆), trisilane (Si₃H₈), dichlorosilane (SiH₂Cl₂), trichlorosilane (SiHCl₃), tetrachlorosilane (SiCl₄), or the like may be used. Instead of phosphine (PH₃), another n-type impurity source such as arsine (AsH₃) or an organic source of any of these substances may be used. Before the epitaxial growth, the surface of the silicon substrate may be cleaned by using a chemical such as hydrofluoric acid (HF), hydrogen (H₂) gas, and so on according to need.

The insulating film 43 that is to serve as a mask at the time of epitaxial growth is formed. This insulating film 43 is formed of e.g. a silicon nitride film. The film thickness thereof is set to e.g. 20 nm. Thereafter, by typical resist application and lithography, an etching mask (not shown) is formed in which an aperture is formed over the region on the other lateral side of the gate electrode 14, i.e., over the region in the first n-region n1 in which the first p-region p1 is to be formed. Subsequently, by an etching technique with use of this etching mask, the insulating film 43 on the region in which the first p-region p1 is to be formed on the other lateral side of the gate electrode 14 is etched. This etching exposes the surface of the semiconductor substrate 11 (first n-region n1) in the region in which the first p-region is to be formed. In this example, a silicon nitride film is used in order to ensure the selectivity at the time of the epitaxial growth. However, another kind of film may be used as long as the selectivity can be ensured. In FIG. 10B and the subsequent drawings, illustration of a lower part of the semiconductor substrate 11 is omitted.

Referring next to FIG. 10B, the recess 19 is formed by etching the first n-region n1 with use of the insulating film 43 and the insulating film 42 as the mask. This recess 19 is formed by etching the semiconductor substrate 11 to a depth of e.g. 100 nm. This etching depth is equivalent to the depth of the junction between the first n-region n1 and the first p-region p1, and therefore may be adequately changed depending on device characteristics. In this etching, the insulating film 43 on the insulating film 42 on one lateral side of the gate electrode 14 may be removed. The drawing shows the case where the insulating film 43 on this side is removed. Alternatively, it may be left.

Referring next to FIG. 10C, the first p-region p1 of the first conductivity type (p-type), formed of an epitaxially grown silicon layer, is formed by selective epitaxial growth in the recess 19 formed in the first n-region n1. As one example of the condition of this selective epitaxial growth, monosilane (SiH₄), diborane (B₂H₆), and hydrogen chloride (HCl) gas are used as the source gas, and the substrate temperature (deposition temperature) is set to 750° C. Furthermore, the condition is so set that a dopant concentration (e.g., boron concentration) of e.g. 1×10²⁰ cm⁻³ is obtained. It is desirable that this dopant concentration be about 1×10¹⁷ cm⁻³ to 1×10²¹ cm⁻³. Instead of monosilane (SiH₄), disilane (Si₂H₆), trisilane (Si₃H₈), dichlorosilane (SiH₂Cl₂), trichlorosilane (SiHCl₃), tetrachlorosilane (SiCl₄), or the like may be used. Furthermore, instead of diborane (B₂H₆), another p-type impurity source such as an organic source may be used. In addition, a silicon germanium (SiGe) film may be deposited instead of the silicon (Si) film by selective epitaxial growth. However, because this film should have a band gap wider than that of the uppermost part of the n-type region (first n-region n1), the composition ratio of silicon (Si) to germanium (Ge) should be adequately adjusted. Before the epitaxial growth, the surface of the silicon substrate may be cleaned by using a chemical such as hydrof luoric acid (HF), hydrogen (H₂) gas, and so on according to need.

After this film deposition, as activation annealing, e.g. spike annealing at 1000° C. for about zero seconds is carried out according to need. The conditions of this annealing may be any as long as the dopants can be activated. This activation annealing may be carried out after the first n-region n1 is formed.

Referring next to FIG. 10D, by a typical electrode formation technique, the anode electrode A connected to the first p-region p1 and the cathode electrode K connected to the second n-region n2 are formed. At this time, it is preferable to form a silicide (TiSi, CoSi, NiSi, or the like) at the both-end exposed parts on the first p-region p1 and the second n-region n2 through a salicide step. After the electrode formation, a wiring step similar to that in a typical CMOS step is carried out.

In the manufacturing method of the fifth embodiment, the first n-region n1 in the thyristor 10 is formed by using a germanium layer or silicon germanium layer having mobility higher than that of silicon. Thus, the mobility of carriers in the first n-region n1 can be enhanced. This can increase the speed of sweeping of the carriers out of the first n-region n1, which can enhance the speed of switching from the on-state to the off-state. Furthermore, because the carrier mobility is enhanced, increase in the speed of switching from the off-state to the on-state can also be expected as a synergetic effect. It is generally known that the carrier mobility of germanium is higher than that of silicon. For example, the mobility of electrons and holes in silicon is 1600 cm²/V·s and 430 cm²/V·s, respectively. In contrast, the mobility of electrons and holes in germanium is 3900 cm²/V·s and 1900 cm²/V·s, respectively. That is, both the mobility of electrons and that of holes in germanium are higher, and in particular, the mobility of holes in germanium is as high as about five times that in silicon. Therefore, by using germanium or silicon germanium, which is a mixture of silicon and germanium with high carrier mobility, as the material of at least the second region, the switching speed of the thyristor 10 formed of the first p-region p1, the first n-region n1, the second p-region p2, and the second n-region n2 can be enhanced. This offers an advantage that the semiconductor device 9 having the high-speed thyristor 10 can be manufactured.

The above-described first to fifth embodiments are based on the premise that a bulk silicon substrate is used as the semiconductor substrate 11. However, the semiconductor devices of the embodiments can be manufactured also by use of an SOI (Silicon on insulator) substrate, GOI (Germanium on insulator) substrate, SiGeOI (Silicon Germanium on insulator) substrate, silicon germanium (SiGe) substrate, or the like.

Furthermore, in the above-described first to fifth embodiments, the n-type regions and p-type regions may be interchanged.

In the first to fifth embodiments, all the epitaxial growth is accompanied by doping. However, all or part of the epitaxially grown layers may be formed by carrying out epitaxial growth without doping and then executing doping with an impurity by ion implantation or solid-state diffusion.

In the second and third embodiments, the recess 18 is formed in the semiconductor substrate (silicon substrate) 11. However, the first n-region n1 may be formed by selective epitaxial growth without the formation of the recess 18 like in the fourth embodiment.

In the first to fifth embodiments, ion implantation is used to form the second n-region n2. However, the second n-region n2 may be formed by selective epitaxial growth in a recess formed in the second p-region p2 for example. Alternatively, without the formation of a recess, the second n-region n2 may be formed on the second p-region p2 by selective epitaxial growth. When the second n-region n2 is formed on the silicon substrate by selective epitaxial growth, a large effective distance between the first n-region n1 and the second n-region n2 can be obtained, which allows the second p-region p2 to have a large thickness. Because the second p-region p2 is equivalent to the base layer in an NPN bipolar device, this scheme permits adjustment of device characteristics.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device comprising
a thyristor configured to be formed through sequential joining of a first region of a first conductivity type, a second region of a second conductivity type opposite to the first conductivity type, a third region of the first conductivity type, and a fourth region of the second conductivity type, and have a gate formed over the third region, wherein
the first to fourth regions are formed in a silicon germanium region or germanium region.

2. The semiconductor device according to claim 1, wherein
the silicon germanium region or germanium region is formed of a silicon germanium layer or germanium layer formed on a semiconductor substrate.

3. A semiconductor device comprising
a thyristor configured to be formed through sequential joining of a first region of a first conductivity type, a second region of a second conductivity type opposite to the first conductivity type, a third region of the first conductivity type, and a fourth region of the second conductivity type, and have a gate formed over the third region, wherein
the second region is formed of a silicon germanium layer or germanium layer.

4. The semiconductor device according to claim 3, wherein
the first region is formed by introducing an impurity of the first conductivity type into the silicon germanium layer or germanium layer.

5. The semiconductor device according to claim 3, wherein
the silicon germanium layer or germanium layer is formed in a recess formed in a silicon semiconductor region in which the third region is formed.

6. The semiconductor device according to claim 5, wherein
the first region is formed on the second region.

7. The semiconductor device according to claim 3, wherein
the second region is formed on a silicon semiconductor region in which the third region is formed.

8. The semiconductor device according to claim 7, wherein
the first region is formed on the second region.

9. The semiconductor device according to claim 3, wherein
the first region is formed in a recess formed in the second region.

10. The semiconductor device according to claim 3, wherein
the second region is formed of a silicon germanium layer formed on a silicon semiconductor region, and a part in the second region closer to the silicon semiconductor region has a higher composition ratio of germanium.

11. A method for manufacturing a semiconductor device that includes a thyristor formed through sequential joining of a first region of a first conductivity type, a second region of a second conductivity type opposite to the first conductivity type, a third region of the first conductivity type, and a fourth region of the second conductivity type, the thyristor having a gate formed over the third region, the method comprising the step of:
forming the first to fourth regions in a silicon germanium region or germanium region.

12. The method for manufacturing a semiconductor device according to claim 11, wherein
the silicon germanium region or germanium region is formed on a semiconductor substrate by epitaxial growth.

13. A method for manufacturing a semiconductor device that includes a thyristor formed through sequential joining of a first region of a first conductivity type, a second region of a second conductivity type opposite to the first conductivity type, a third region of the first conductivity type, and a fourth region of the second conductivity type, the thyristor having a gate formed over the third region, the method comprising the step of:
forming the second region by using a silicon germanium layer or germanium layer.

14. The method for manufacturing a semiconductor device according to claim 13, wherein
the first region is formed by introducing an impurity of the first conductivity type into the silicon germanium layer or germanium layer.

15. The method for manufacturing a semiconductor device according to claim 13, wherein
the silicon germanium layer or germanium layer is formed by forming a recess in a silicon semiconductor region in which the third region is formed and growing silicon germanium or germanium in the recess by epitaxial growth.

16. The method for manufacturing a semiconductor device according to claim 15, wherein
the first region is formed on the second region.

17. The method for manufacturing a semiconductor device according to claim 13, wherein
the second region is formed on a silicon semiconductor region in which the third region is formed.

18. The method for manufacturing a semiconductor device according to claim 17, wherein
the first region is formed on the second region.

19. The method for manufacturing a semiconductor device according to claim 13, wherein
the first region is formed by forming a recess in the second region and growing silicon germanium or germanium in the recess by epitaxial growth.

20. The method for manufacturing a semiconductor device according to claim 13, wherein
the second region is formed on a silicon semiconductor region by using a silicon germanium layer in such a way that a part in the second region closer to the silicon semiconductor region has a higher composition ratio of germanium.
